(19) United States
(12) Patent Application Publication
(10) Pub. No.: US 2007/0076772 A1
(43) Pub. Date: Apr. 5, 2007

(54) Semiconductor laser device

(76) Inventors: Takeshi Horiguchi, Higashihiroshima-shi (JP); Masahiro Ikehara, Higashihiroshima-shi (JP); Fumio Torimatsu, Higashihiroshima-shi (JP)

Correspondence Address: MORRISON & FOERSTER LLP, 755 PAGE MILL RD, PALO ALTO, CA, 94304-1018, US

(21) Appl. No.: 11/541,326

(22) Filed: Sep. 28, 2006

(30) Foreign Application Priority Data
Sep. 30, 2005 (JP) P2005-288168
Sep. 11, 2006 (JP) P2006-246157

(51) Int. Cl. H01S 5/00

(52) U.S. Cl. 372/43.01

(57) ABSTRACT

Provided is a semiconductor laser device with a ridge waveguide that is excellent in polarization characteristics and easiness of mounting. In its outermost part on which the solder layer is deposited, the incomplete adherent layer is formed at least in the ridge structure. In bonding the semiconductor laser device to the mount via the solder layer, the incomplete adherent layer is not adhered or adhered incompletely to the solder layer. On either side of the incomplete adherent layer is formed the complete adherent layer.

### BACKGROUND OF THE INVENTION

1. Field of the Invention

The present invention relates to a semiconductor laser device designed for use in, for example, an optical pickup which is incorporated into an optical disk system.

2. Description of the Related Art

A semiconductor laser apparatus disclosed in Japanese Unexamined Patent Publication JP-A 9-64479 (1997) is constructed of a semiconductor substrate in combination with a rib waveguide. In this construction, the laser lower electrode thereof is composed of three layers, namely an ohmic contact layer, a non-alloying metal layer, and an alloying electrode layer. The ohmic contact layer makes ohmic contact with a cap layer. The non-alloying metal layer is made of a metal having a high melting point that is not alloyed with a solder layer. The non-alloying metal layer is formed on the surface of the ohmic contact layer. The alloying electrode layer, which is alloyed with the solder layer 8, is vertically spaced by more than a prescribed interval away from immediately below the center line in the longitudinal direction of a light emitting region 5 of the surface of the non-alloying metal layer. The non-alloying metal layer and the solder layer are in contact but not alloyed with each other. The alloying electrode layer and the solder layer in contact therewith are alloyed with each other. Through the solder layer, a semiconductor laser device is adhered to a heat sink.

In a semiconductor laser apparatus disclosed in Japanese Unexamined Patent Publication JP-A 2004-14659, a concave groove is formed on either side of the active layer and ridge structure, and an electrode membrane is so formed as to extend across the opposite ends of the construction while covering the surfaces of the ridge structure and the concave groove. Moreover, a solder layer for joining together the semiconductor laser device of the semiconductor laser apparatus and a mount substrate is formed on either side of the concave groove to secure a space between the mount substrate and the ridge structure with the concave groove.

A semiconductor laser apparatus disclosed in Japanese Unexamined Patent Publication JP-A 11-87849 (1999) is constructed by bonding a semiconductor laser device onto a Si substrate with use of a solder layer. In this construction, under the active layer thereof is formed a cavity to create a soldering-free region.

According to JP-A 9-64479 (1997), when applied to a semiconductor laser device having a rib waveguide, the disclosed technique makes it possible to alleviate an internal stress generated in the light emitting region due to the difference in thermal expansion coefficient between the heat sink and the semiconductor laser device, and thereby increase the service life and yields of the semiconductor laser device. However, when applied to a semiconductor laser device having a ridge waveguide, the disclosed technique fails to live up to expectation of achieving an improvement in light emission characteristics.

According to JP-A 2004-14659, the solder layer needs to be formed in such a manner as to create a space in the face of the ridge structure and the concave groove. In this case, the solder layer cannot be deposited over the entire deposition surface of the semiconductor laser device, thus making it difficult to mount the semiconductor laser device onto a sub mount.

According to JP-A 11-87849 (1999), it is necessary to create a cavity region in the solder layer which is formed for connecting the semiconductor laser device to the substrate. Also in this case, the solder layer cannot be deposited over the entire deposition surface of the semiconductor laser device, thus making it difficult to mount the semiconductor laser device onto a sub mount.

Moreover, neither JP-A 9-64479 (1997) nor JP-A 11-87849 (1999) discloses such a configuration as is capable of achieving an improvement in polarization characteristics when applied to a semiconductor laser apparatus having a ridge waveguide which is more susceptible to a stress than a rib waveguide.

### SUMMARY OF THE INVENTION

An object of the invention is to provide a semiconductor laser device having a ridge waveguide that is excellent in light emission characteristics, especially polarization characteristics, and easiness of mounting.

The invention provides a semiconductor laser device that is bonded to a mount via a solder layer, comprising:

a ridge structure including a stripe-shaped ridge waveguide that is disposed on a semiconductor substrate;

an electrically conductive incomplete adherent layer which is formed at least in the ridge structure and is to be an outermost surface portion of the semiconductor laser device that is located outwardly of the ridge waveguide and on which is deposited the solder layer, the incomplete adherent layer being brought into contact with the solder layer in an incompletely-adherent state; and

an electrically conductive complete adherent layer which is formed on either side of the incomplete adherent layer and is to be other outermost surface portions of the semiconductor laser device that are located outwardly of the ridge waveguide and on which is deposited the solder layer, when viewed in a direction perpendicular to a direction of thickness of the semiconductor substrate as well as a direction in which the ridge waveguide extends, the complete adherent layer being brought into contact with the solder layer in a completely-adherent state.

According to the invention, with respect to the outermost surface portions of the semiconductor laser device that are located outwardly of the ridge waveguide and on which is deposited the solder layer, the electrically conductive incomplete adherent layer is formed at least in the ridge structure. The incomplete adherent layer is brought into contact with the solder layer in an incompletely-adherent state. At the time of bonding the semiconductor laser device to the mount via the solder layer, the incomplete adherent layer is not adhered to the solder layer or adhered to the solder layer incompletely, if any. In this case, when the solder layer undergoes thermal expansion and contraction, a resultant stress can be exerted uniformly upon the ridge structure. Moreover, it is possible to alleviate a stress which is developed in the ridge structure in accompaniment with laser light emission due to the difference in thermal expansion and contraction between the semiconductor laser device and the amount. This helps suppress distortion which arises in the ridge structure through application of stress. Since the ridge structure suffers little from distortion, it follows that a stress exerted upon the active layer can be reduced, thus suppressing distortion which arises in the active layer. As a result, the polarization characteristics of laser light can be improved; that is, the laser light can be polarized at an increased polarization ratio and at a decreased polarization angle.

Moreover, with respect to the outermost surface portions of the semiconductor laser device that are located outwardly of the ridge waveguide and on which is deposited the solder layer, the electrically conductive complete adherent layer is formed on either side of the incomplete adherent layer, when viewed in the direction perpendicular to the direction of thickness of the semiconductor substrate as well as the direction in which the ridge waveguide extends. This makes it possible to strengthen the mechanical coupling between the semiconductor laser device and the mount.

The outermost surface of the semiconductor laser device on which is deposited the solder layer are composed of the incomplete adherent layer and the complete adherent layer. That is, the semiconductor laser device is mounted onto the mount via the solder layer deposited on the incomplete adherent layer and the complete adherent layer. In this case, the solder layer can be deposited over the entirety of the outermost surface without the necessity of being subjected to processing in some way, thus facilitating the mounting of the semiconductor laser device onto the mount.

In the invention, it is preferable that the incomplete adherent layer is composed of:

a first incomplete adherent layer formed centrally of the semiconductor laser device when viewed in the direction perpendicular to the direction of thickness of the semiconductor substrate as well as the direction in which the ridge waveguide extends; and

a second incomplete adherent layer formed on either side of the first incomplete adherent layer when viewed in the direction perpendicular to the direction of thickness of the semiconductor substrate as well as the direction in which the ridge waveguide extends, the second incomplete adherent layer being designed to fall in between the first incomplete adherent layer and the complete adherent layer in terms of wettability with respect to a solder material used to form the solder layer.

According to the invention, of the incomplete adherent layer, the first incomplete adherent layer is located closer to the ridge structure, whereas the second incomplete adherent layer is located between the first incomplete adherent layer and the complete adherent layer, when viewed in the direction perpendicular to the direction of thickness of the semiconductor substrate as well as the direction in which the ridge waveguide extends. The first incomplete adherent layer is wet poorly by the solder material constituting the solder layer. On the other hand, the second incomplete adherent layer falls in between the first incomplete adherent layer and the complete adherent layer in terms of wettability with respect to the solder material constituting the solder layer. With this arrangement, the semiconductor laser device is so designed that the strength of bonding between the outermost surface on which is deposited the solder layer and the solder layer becomes higher gradually from the center, namely the ridge structure to the edge. By doing so, it is possible to avoid the steep change in stress that could occur in the region where the complete adherent layer and the incomplete adherent layer are adjacent to each other due to a stress developed in the complete adherent layer and a stress developed in the incomplete adherent layer. As a result, the stress exerted upon the ridge waveguide can be alleviated, wherefore the degree of distortion in the ridge waveguide can be reduced even further.

In the invention, it is preferable that the first incomplete adherent layer, the second incomplete adherent layer, and the complete adherent layer are made of molybdenum (Mo), platinum (Pt), and gold (Au), respectively.

According to the invention, the first incomplete adherent layer, the second incomplete adherent layer, and the complete adherent layer are made of molybdenum (Mo), platinum (Pt), and gold (Au), respectively. By selecting metal materials in that way, it is possible to achieve the above stated effects, as well as to form the first and second incomplete adherent layers and the complete adherent layer with ease by means of conventionally-known layer deposition technique without the necessity of coming up with a new method.

In the invention, it is preferable that, when viewed in the direction perpendicular to the direction of thickness of the semiconductor substrate as well as the direction in which the ridge waveguide extends, a terrace portion is formed on either side of the ridge waveguide, with a predetermined distance secured therebetween to create a concavity extending from the ridge waveguide to the terrace portion.

In order for the semiconductor laser device to be bonded to the sub mount via the solder layer, application of a predetermined load is necessary to press the semiconductor laser device against the mount properly. In this respect, according to the invention, when viewed in the direction perpendicular to the direction of thickness of the semiconductor substrate as well as the direction in which the ridge waveguide extends, the terrace portion is formed on either side of the ridge waveguide, with a predetermined distance secured therebetween to create a concavity extending from the ridge waveguide to the terrace portion. In this case, the load imposed upon the ridge structure can be dispersed over the terrace portions, wherefore the stress exerted upon the ridge structure due to the pressing force can be alleviated correspondingly. As a result, the ridge structure suffers little from distortion at the time of mounting the semiconductor laser device onto the mount.

In the invention, it is preferable that the concavity has formed in its ridge waveguide-sided part the incomplete adherent layer, and has formed in its terrace portion-sided part the complete adherent layer.

According to the invention, the concavity has formed in its ridge structure-sided part the incomplete adherent layer. This helps reduce the stress applied to the ridge structure through its environs even further. Moreover, the concavity has formed in its terrace portion-sided part the complete adherent layer. When heat is generated in the ridge structure in accompaniment with laser light emission, it is difficult to achieve good heat dissipation at the interface between the ridge structure and the solder layer. However, with the complete adherent layer, the generated heat can be dissipated efficiently from the complete adherent layer into the semiconductor layer.

In the invention, it is preferable that a part of the incomplete adherent layer which is located in the concavity extends from a position of the ridge waveguide partway to a position of the terrace portion by a predetermined length which is adjusted to be 30% or more and less than 50% of a distance between the ridge waveguide and the terrace portion.

According to the invention, in a case where the part of the incomplete adherent layer which is located in the concavity is so formed as to extend from the ridge waveguide partway to the terrace portion by a length set at or above 30% of the distance between the ridge waveguide and the terrace portion, the effect of stress reduction can be enhanced more reliably. By way of contrast, in a case where the part of the incomplete adherent layer which is located in the concavity is so formed as to extend from the ridge waveguide partway to the terrace portion by a length not less than 50% of the distance between the ridge waveguide and the terrace portion, it is difficult to readily dissipate the heat generated in the ridge waveguide into the alloying layer. This leads to deterioration in the amperage characteristics of the semiconductor laser device, thus causing an undesirable decrease in light emission efficiency. It is thus preferable that the part of the incomplete adherent layer which is located in the concavity extends from the position of the ridge waveguide partway to the position of the terrace portion by a predetermined length which is adjusted to be 30% or more and less than 50% of the distance between the ridge waveguide and the terrace portion. In this way, the stress exerted upon the ridge waveguide can be alleviated without fail, and deterioration in the amperage characteristics of the semiconductor laser device can be suppressed successfully.

In the invention, it is preferable that a part of the complete adherent layer which is located in the concavity extends from a position of the terrace portion partway to a position of the ridge waveguide by a predetermined length which is set at or below 50% of the distance between the ridge waveguide and the terrace portion.

According to the invention, in a case where the part of the complete adherent layer which is located in the concavity is so formed as to extend from the terrace portion partway to the ridge waveguide by a length greater than 50% of the distance between the ridge waveguide and the terrace portion, although deterioration in the amperage characteristics of the semiconductor laser device can be suppressed by the effect of dissipating heat from the complete adherent layer into the solder layer efficiently, the stress developed in the complete adherent layer is liable to propagate through the ridge structure. It is thus preferable that the part of the complete adherent layer which is located in the concavity extends from the position of the terrace portion partway to the position of the ridge waveguide by a predetermined length which is set at or below 50% of the distance between the ridge waveguide and the terrace portion. In this way, not only it is possible to suppress deterioration in the amperage characteristics of the semiconductor laser device, but it is also possible to inhibit the stress developed in the complete adherent layer from propagating through the ridge structure and thereby avoid occurrence of distortion in the ridge structure.

In the invention, it is preferable that the semiconductor laser device further includes an under coating metal layer made of gold (Au) on which are deposited the complete adherent layer and the incomplete adherent layer.

According to the invention, the heat generated in the ridge structure is transmitted through the under coating metal layer made of gold (Au) having a high thermal conductivity to the complete adherent layer, and is then dissipated into the mount through the solder layer. In this way, good heat dissipation can be achieved in the region between the incomplete adherent layer and the solder layer, thus suppressing deterioration in the current characteristics of the semiconductor laser device more reliably. As a result, the semiconductor laser device can be built to ensure a longer service life.

In the invention, it is preferable that the semiconductor laser device further includes an under coating metal layer on which are deposited the complete adherent layer and the incomplete adherent layer,

wherein the under coating metal layer is formed by sequentially depositing a plate electrode layer made of gold (Au) and formed by plating, a first electrode layer made of a predetermined metal, and a second electrode layer made of gold (Au).

Since the plate electrode layer made of gold is formed by plating, it is possible to form a layer having a large thickness in a short period of time, compared to the case of forming the layer made of gold by the sputtering method. However, the plate electrode layer made of gold has deteriorated surface flatness and changing wettability depending on plating conditions. Accordingly, an adhesive property of the plate electrode layer may have variations. According to the invention, the under coating metal layer includes the metal electrode layer made of gold, but in the under coating metal layer are sequentially deposited a first electrode layer made of a predetermined metal whose surface flatness is better than that of the plate electrode layer, and a second electrode layer made of metal. By so doing, it is possible to enhance surface flatness of the second electrode layer. It is thus possible to enhance an adhesive property between the second electrode layer and the complete adherent layer and incomplete adherent layer which are deposited on the second electrode layer, so that the under coating metal layer and the complete adherent layer and incomplete adherent layer are prevented from being peeled off from each other. Consequently, the heat generated in the ridge structure can be transmitted through the under coating metal layer containing gold (Au) having a high thermal conductivity to the complete adherent layer, and then reliably dissipated into the mount through the solder layer. In this way, good heat dissipation can be achieved in the region between the incomplete adherent layer and the solder layer, thus suppressing deterioration in the current characteristics of the semiconductor laser device more reliably. As a result, the semiconductor laser device can be built to ensure a longer service life.

In the invention, it is preferable that the predetermined metal which forms the first electrode layer is selected from the group consisting of molybdenum (Mo), platinum (Pt), molybdenum-platinum (Moat), and titanium (Ti).

According to the invention, the predetermined metal which forms the first electrode layer is selected from the group consisting of molybdenum (Mo), platinum (Pt), molybdenum-platinum (Moat), and titanium (Ti). The molybdenum (Mo), platinum (Pt), molybdenum-platinum (Moat), and titanium (Ti) bring the electrode layer made thereof excellent surface flatness, so that the above stated effects can be achieved.

In the invention, it is preferable that the first electrode layer and the second electrode layer are formed by continuous deposition of a sputtering method.

According to the invention, the first electrode layer and the second electrode layer are formed by continuous deposition of a sputtering method, and therefore able to enhance adhesion thereof to the plate electrode layer made of gold. Furthermore, even when a surface of the plate electrode layer contains concavities and convexities, the first electrode layer and the second electrode layer are formed so as to pervade every part of the concavities and convexities so that a thickness of the under coating electrode layer can be made as uniform as possible. The more uniformed thickness of the under coating electrode layer can lead a more stabilized bonding property and an enhanced adhesion. This brings effects such that a problem of insufficient heat dissipation can be solved, that current characteristics can be suppressed from being deteriorated, and that a service life of the semiconductor laser device can be made longer.

In the invention, it is preferable that the thickness of the under coating metal layer is selected to be 0.5 μm or more and less than 5.0 μm.

According to the invention, if the thickness of the under coating metal layer is less than 0.5 μm, a satisfactory heat-transmission effect cannot be attained. On the other hand, if the thickness exceeds 5.0 μm, a stress generated in accompaniment with the formation of the under coating metal layer is transmitted to the ridge waveguide, thus causing distortion in the ridge waveguide. By adjusting the thickness of the under coating metal layer in a range of from 0.5 μm to 5.0 μm, it is possible to transmit heat from the ridge waveguide to the complete adherent layer satisfactorily, as well as to alleviate the stress exerted upon the ridge waveguide.

In the invention, it is preferable that the semiconductor laser device further includes a back-side metal layer formed on the opposite surface of the semiconductor substrate from the surface on which is disposed the ridge structure.

According to the invention, the semiconductor laser device has the back-side metal layer made of gold (Au) formed on the opposite surface of the semiconductor substrate from the surface on which is disposed the ridge structure. In the presence of the back-side metal layer, the stress generated in accompaniment with the formation of the under coating metal layer can be alleviated successfully.

### BRIEF DESCRIPTION OF THE DRAWINGS

Other and further objects, features, and advantages of the invention will be more explicit from the following detailed description taken with reference to the drawings wherein:

FIG. 1 is a sectional view of a semiconductor laser device in accordance with one embodiment of the invention;

FIG. 2 is a plan view of the semiconductor laser device;

FIGS. 3A through 3C are sectional views showing how the semiconductor laser device is fabricated;

FIGS. 4A through 4D are sectional views showing how the semiconductor laser device is fabricated;

FIGS. 5A through 5C are sectional views showing how the semiconductor laser device is fabricated;

FIG. 6 is a sectional view showing a semiconductor laser apparatus constructed by mounting the semiconductor laser device onto a mount, with a solder layer lying therebetween;

FIG. 7 is a sectional view showing a semiconductor laser device in accordance with still another embodiment of the invention;

FIG. 8 is a plan view of the semiconductor laser device;

FIG. 9 is a sectional view showing a semiconductor laser apparatus constructed by mounting the semiconductor laser device onto the mount, with the solder layer lying therebetween;

FIG. 10 is a sectional view showing a semiconductor laser device in accordance with still another embodiment of the invention; and

FIG. 11 is a section view showing a semiconductor laser device in accordance with still another embodiment of the invention.

### DETAILED DESCRIPTION

Now referring to the drawings, preferred embodiments of the invention are described below.

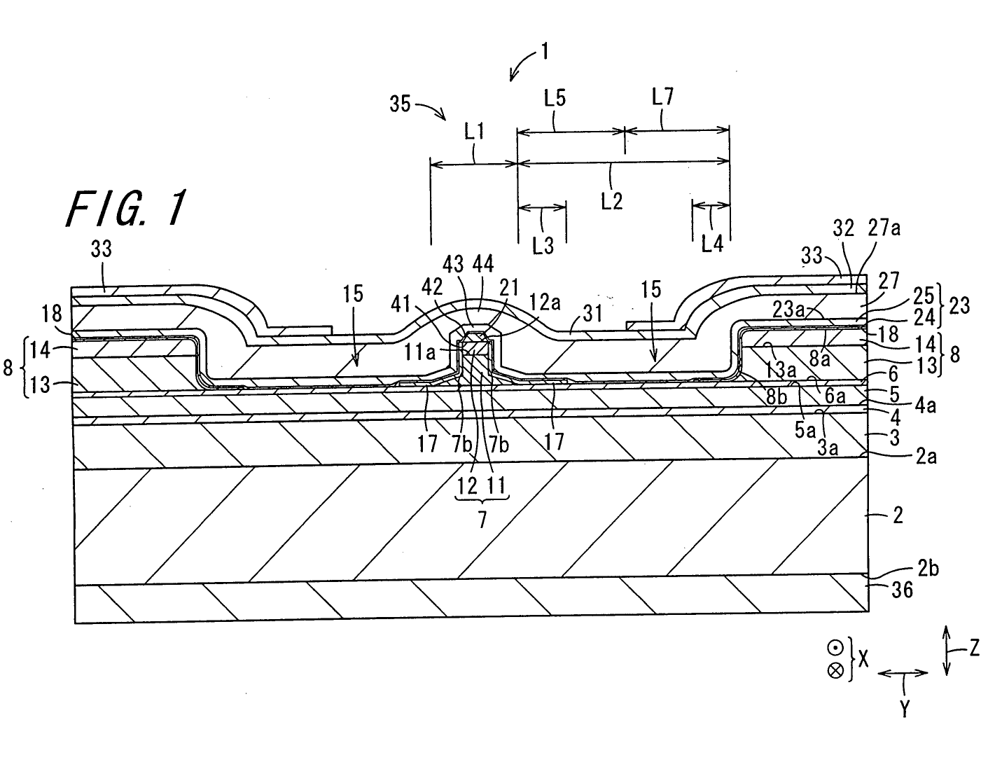

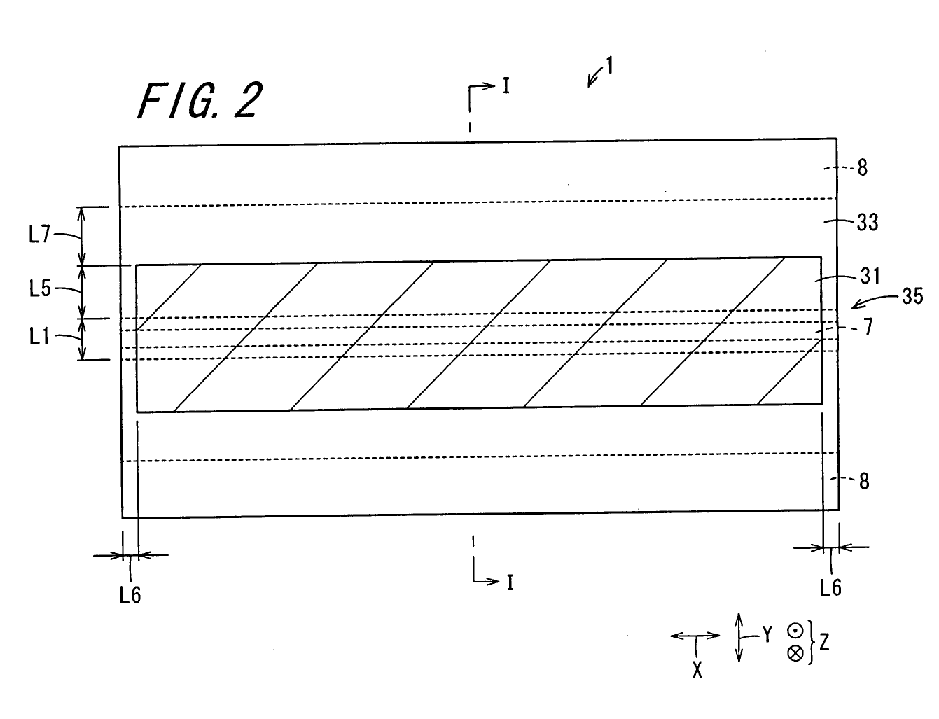

FIG. 1 is a sectional view of a semiconductor laser device 1 in accordance with one embodiment of the invention. FIG. 2 is a plan view of the semiconductor laser device 1. FIG. 1 is a sectional view taken along the line I-I of FIG. 2. Note that the direction of thickness of a semiconductor substrate 2 constituting the semiconductor laser device 1 is defined as a thickness wise direction Z (Z direction). FIG. 2 illustrates one Z direction-wise side of the semiconductor substrate 2 on which is formed a ridge structure 35. In FIG. 2, for the sake of simplifying an understanding of the illustration, an incomplete adherent layer 31 is diagonally shaded. The semiconductor laser device 1 is built as a semiconductor laser chip. The thickness wise direction Z of the semiconductor substrate 2 is parallel to a depositing direction of respective semiconductor layers and respective metal layers which form the semiconductor laser device. The semiconductor laser device 1 is composed of the semiconductor substrate 2, a first clad layer 3, an active layer 4, a second clad layer 5, an etching stop layer 6, a ridge portion 7, a terrace portion 8, a first and a second dielectric layer 17 and 18, a plating base electrode layer 23, a plate electrode layer 27, a metal layer 32 including the incomplete adherent layer 31, and a complete adherent layer 33.

The semiconductor substrate 2 can be constructed of a compound semiconductor layer deposition. In the present embodiment, n-type gallium arsenide (GaAs) is employed therefor. The semiconductor substrate 2 has a quadrilateral cross-sectional profile when viewed in the thickness wise direction Z. The thickness of the semiconductor substrate 2 is selected to fall in a range of from 50 μm to 130 μm, for example.

The first clad layer 3 is deposited over the entire one Z direction-wise surface 2a of the semiconductor substrate 2 with use of n-type (Alₓ Ga₁₋ₓ) _{Y}In_{1-Y} P, wherein the following conditions have to be satisfied: 0<X<1 and 0<Y<1. In the present embodiment, the value of X is set at 0.7, and the value of Y is set at 0.5. That is, the first clad layer 3 is made of n-type (Al_{0.7}Ga_{0.3}) _{0.5}In_{0.5} P. The thickness of the first clad layer 3 is set at 2.0 μm, for example.

The active layer 4 is deposited over the entire one Z direction-wise surface 3a of the first clad layer. The active layer 4 takes on a quantum well structure composed of a first guide layer deposited on one Z direction-wise surface 3a of the first clad layer 3, a first well layer deposited on one Z direction-wise surface of the first guide layer, a barrier layer deposited on one Z direction-wise surface of the first well layer, a second well layer deposited on one Z direction-wise surface of the barrier layer, and a second guide layer deposited on one Z direction-wise surface of the second well layer. The first and second well layers a remade of In_{0.5}Ga_{0.5} P, the thickness of which is set at 80 Å, for example. The barrier layer is made of (Al_{0.7}Ga_{0.3}) _{0.5}In_{0.5} P, the thickness of which is set at 50 Å, for example. The guide layer is made of (Al_{0.7}Ga_{0.3}) _{0.5}In_{0.5} P, the thickness of which is set at 300 Å, for example.

The second clad layer 5 is deposited over the entire one Z direction-wise surface 4a of the active layer 4 with use of p-type (AlₓGa₁₋ₓ) _{Y}In_{1-Y} P, wherein the following conditions have to be satisfied: 0<X<1 and 0<Y<1. In the present embodiment, the value of X is set at 0.7, and the value of Y is set at 0.5. That is, the second clad layer 5 is made of p-type (Al_{0.7}Ga_{0.3}) _{0.5}In_{0.5} P. The thickness of the second clad layer 5 is selected to fall in a range of from 0.2 μm to 0.3 μm, for example.

The etching stop layer 6 is deposited over the entire one Z direction-wise surface 5a of the second clad layer 5. The etching stop layer 6 is made of p-type In_{0.5} Ga_{0.5} P, the thickness of which is set at 50 A, for example. In the presence of the etching stop layer 6, the second clad layer 5 is kept out of etching.

Formed on one Z direction-wise surface 6a of the etching stop layer 6 is the ridge portion 7 composed of a third clad layer 11 and a cap layer 12. Note that the direction of width of the semiconductor laser device 1 is defined as a widthwise direction Y (Y direction). When viewed in the widthwise direction Y the ridge portion 7 is formed centrally of the semiconductor laser device 1 so as to protrude from one Z direction-wise surface 6a of the etching stop layer 6 in the thickness wise direction Z. The semiconductor laser device 1 is designed substantially surface-symmetrical about a virtual plane passing through the Y direction-wise center in parallel with the thickness wise direction Z. The stripe-shaped ridge portion 7 extends in a direction perpendicular to both the thickness wise direction Z and the widthwise direction Y, namely a direction in which laser light is emitted. The laser-light emission direction, namely the direction in which the ridge portion 7 extends is defined as a direction X. When viewed in the direction X, the ridge portion 7 is so formed as to extend across both ends of the semiconductor laser device 1.

The third clad layer 11 is deposited on one Z direction-wise surface 6a of the etching stop layer 6. The third clad layer 11 is made of p-type (Alₓ Ga₁₋ₓ) _{Y}In_{1-Y} P, wherein the following conditions have to be satisfied: 0<X<1 and 0<Y<1. In the present embodiment, the value of X is set at 0.7, and the value of Y is set at 0.5. That is, the third clad layer 11 is made of p-type (Al_{0.7} Ga_{0.3}) _{0.5}In_{0.5} P. The thickness of the third clad layer 11 is selected to fall in a range of from 300 nm to 5000 nm, for example. The third clad layer 11 constitutes a ridge waveguide through which laser light is directed.

The cap layer 12 made of gallium arsenide (GaAs) is deposited on one Z direction-wise surface 11a of the third clad layer 11 to gain an ohmic contact with a ridge top electrode layer 21 which will be described later on.

Given the ridge portion 7's dimension of L1 when viewed in the widthwise direction Y, then L1 is selected to fall in a range of from 1.5 μm to 3.0 μm. More specifically, when viewed in the widthwise direction Y, the dimension of one Z direction-wise end of the ridge portion 7, namely one end of the ridge portion 7 located away from the semiconductor substrate 2 is selected to fall in a range of from 0.1 μm to 0.3 μm, whereas the dimension of the other Z direction-wise end of the ridge portion 7, namely the other end of the ridge portion 7 kept in contact with the etching stop layer 6 is selected to fall in a range of from 1.5 μm to 3.0 μm. When viewed in the direction perpendicular to the direction X in which the ridge portion 7 extends, the ridge portion 7 has a trapezoidal cross-sectional profile, the lower side of the trapezoid facing the semiconductor substrate 2.

The terrace portion 8 is composed of a first terrace constituting layer 13 and a second terrace constituting layer 14. When viewed in the widthwise direction Y, the terrace portion 8 is formed on either side of the ridge portion 7, or the ridge waveguide. A predetermined distance L2 is secured between the terrace portion 8 and the ridge portion 7 to create a concavity 15 extending along the direction X in which the ridge portion 7 extends. The predetermined distance L2 is selected to fall in a range of from 10 μm to 20 μm. The stripe-shaped terrace portion 8 is so formed as to extend in the direction X; that is, extend in parallel with the ridge portion 7. When viewed in the width wise direction Y, the terrace portion 8 is so formed as to extend from the edge of the semiconductor laser device 1 to a position located the predetermined distance L2 away from the ridge portion 7.

The first terrace constituting layer 13 is deposited on one Z direction-wise surface 6a of the etching stop layer 6. The first terrace constituting layer 13 is identical in material and thickness with the third clad layer 11. The second terrace constituting layer 14 is deposited on one Z direction-wise surface 13a of the first terrace constituting layer 13. The second terrace constituting layer 14 is identical in material and thickness with the cap layer 12. That is, the ridge portion 7 and the terrace portion 8 have the same thickness. By virtue of the terrace portion 8, it is possible to reduce the hazard of mechanical damage to the ridge portion 7 at the time of working with a wafer on which is formed a precursor of the semiconductor laser device 1 during the process of manufacture of the semiconductor laser device 1, as well as the time of mounting the semiconductor laser device 1.

In the ridge portion 7, its side face 7b facing the terrace portion 8 is covered with the first dielectric layer 17. The first dielectric layer 17 further extends a predetermined distance L3 from the side face 7b of the ridge portion 7 along the widthwise direction Y partway to the terrace portion 8. The first dielectric layer 17 thereupon covers the contact area between the third clad layer 11 and the etching stop layer 6, and further extends over part of one Z direction-wise surface 6a of the etching stop layer 6.

In the terrace portion 8, its one Z direction-wise surface 8a and side face 8b facing the ridge portion 7 are each covered with the second dielectric layer 18. The second dielectric layer 18 further extends a predetermined distance L4 from the side face 8b of the terrace portion 8 along the widthwise direction Y partway to the ridge portion 7. The second dielectric layer 18 thereupon covers the contact area between the first terrace constituting layer 13 and the etching stop layer 6, and further extends over part of one Z direction-wise surface 6a of the etching stop layer 6.

The first and second dielectric layers 17 and 18 are each made of SiO₂, the thickness of which is selected to fall in a range of from 1000 Å to 3000 Å.

Deposited over the entire one Z direction-wise surface of the ridge portion 7, namely one Z direction-wise surface 12a of the cap layer 12 is the AuZn-made ridge top electrode layer 21 formed by an alloying reaction in an atmosphere of nitrogen gas. When viewed in the direction perpendicular to the direction X in which the ridge portion 7 extends, the ridge top electrode layer 21 has a trapezoidal cross-sectional profile, the lower side of the trapezoid facing the semiconductor substrate 2.

The plating base electrode layer 23 is deposited in such a manner as to cover the first and second dielectric layers 17 and 18, the ridge top electrode layer 21, and a part of one Z direction-wise surface 6a of the etching stop layer 6 which is not covered with the first and second dielectric layers 17 and 18. The plating base electrode layer 23 is composed of a first plating underlayer 24 and a second plating underlayer 25. The first plating underlayer 24, which is made of titanium (Ti), is deposited in such a manner as to cover the first and second dielectric layers 17 and 18, the ridge top electrode layer 21, and the part of one Z direction-wise surface 6a of the etching stop layer 6 which is not covered with the first and second dielectric layers 17 and 18. The thickness of the first plating underlayer 24 is selected to fall in a range of from 300 Å to 2000 Å, for example. The second plating underlayer 25, which is made of gold (Au), is deposited on one Z direction-wise surface 24a of the first plating underlayer 24. The plating base electrode layer 23 is provided for the purpose of forming the plate electrode layer 27, which will be described later on, by means of plating during the process of manufacture of the semiconductor laser device 1. The thickness of the second plating underlayer 25 is selected to fall in a range of from 500 Å to 3000 Å, for example.

The contact area between the first plating underlayer 24 and the etching stop layer 6 presents a light absorptive action. Therefore, in the vicinity of the ridge portion 7, the first dielectric layer 17 is interposed between the first plating underlayer 24 and the etching stop layer 6 to avoid light absorption. The predetermined distance L3 is selected to fall in a range of from 3 μm to 7 μm, and the predetermined distance L4 is also selected to fall in a range of from 3 μm to 7 μm. If the predetermined distance L3 is less than 3 μm, there is an undesirable decrease in light emission efficiency. If the predetermined distance L3 exceeds 7 μm, there is no improvement effect of a far field pattern (abbreviated as FFP). On the other hand, if the predetermined distance L4 is less than 3 μm, it becomes impossible to apply a dielectric film layer to the side face of the terrace portion 8 properly, in consequence whereof there results no FFP improvement effect. If the predetermined distance L4 exceeds 7 μm, no FFP improvement effect can be obtained, too. By providing a light absorber between the ridge portion 7 and the terrace portion 8, it is possible to achieve an improvement in FFP while suppressing occurrence of ripples. That is, laser light can be emitted with reduced ripples by suppressing disorders in FFP.

Deposited over the entire one Z direction-wise surface 23a of the plating base electrode layer 23 is the plate electrode layer 27. The plate electrode layer 27, or the under coating metal layer is made of gold (Au), the thickness of which is selected to be 0.5 μm or more and less than 5.0 μm.

On one Z direction-wise surface 27a of the plate electrode layer 27 is deposited the metal layer 32 including the incomplete adherent layer 31. For example, the metal layer 32 is made of molybdenum (Mo) and therefore the incomplete adherent layer 31 exhibits electrical conductivity. The thickness of the metal layer 32 is selected to fall in a range of from 0.05 μm to 0.30 μm.

The incomplete adherent layer 31 is included at least in a part of the metal layer 32 which constitutes the ridge structure 35. That is, the incomplete adherent layer 31 is an outermost surface portion of the semiconductor laser device 1 that is located outwardly of the ridge waveguide and on which is deposited a solder layer 61 via which the semiconductor laser device 1 is attached to a mount 62 which will be described later on, the incomplete adherent layer 31 is formed at least in the ridge structure.

In the semiconductor laser device 1, the ridge structure 35 is composed of the ridge portion 7, a first ridge deposition portion 41, the ridge top electrode layer 21, a second ridge deposition portion 42, a third ridge deposition portion 43, and a fourth ridge deposition portion 44. The first ridge deposition portion 41 refers to a part of the first dielectric layer 17 which is deposited on the ridge portion 7. The second ridge deposition portion 42 refers to a part of the plating base electrode layer 23 which is deposited on the ridge portion 7 via the first dielectric layer 17 or the ridge top electrode layer 21. The third ridge deposition portion 43 refers to a part of the plate electrode layer 27 which is deposited on the second ridge deposition portion 42. The fourth ridge deposition portion 44 refers to a part of the metal layer 32 which is deposited on the third ridge deposition portion 43. That is, in the semiconductor laser device 1 as seen in the widthwise direction Y, the layer stacking arrangement centrally placed on one Z direction-wise surface 6a of the etching stop layer 6 constitutes the ridge structure 35, the Y direction-wise dimension of which is equivalent to the distance L1 indicated by arrow in FIG. 1, namely the length from one end to the other of the etching stop layer 6-sided surface of the ridge portion 7.

The incomplete adherent layer 31 is also formed in the ridge waveguide-sided part of the concavity 15. The incomplete adherent layer 31 portion located in the concavity 15 extends a predetermined distance L5 from the ridge waveguide, or the ridge portion 7 partway to the terrace portion 8. The predetermined distance L5 is selected to be 30% or more and less than 50% of the predetermined distance L2 between the ridge portion 7 and the terrace portion 8.

When viewed in the direction X in which the ridge portion 7 extends, the incomplete adherent layer 31 is so formed as to extend across both ends of the semiconductor laser device 1, with a predetermined distance L6 secured between each end of the incomplete adherent layer 31 and the corresponding end face, namely light-emitting surface of the semiconductor laser device 1. The predetermined distance L6 is selected in a manner so as to insure that on the light-emitting surface of the semiconductor laser device 1 is formed a coating film for protection of the light-emitting end face from breakage. By selecting the predetermined distance L6 in that way, it is possible to protect the coating film to be formed on the semiconductor laser device 1 against breakage.

On one Z direction-wise surface 32a of the metal layer 32, except for the region in which there is present the incomplete adherent layer 31, is deposited the complete adherent layer 33. The complete adherent layer 33 is made of gold (Au), the thickness of which is selected to fall in a range of from 0.1 μm to 0.4 μm, preferably set at approximately 0.12 μm. The complete adherent layer 33 is an outermost surface portion of the semiconductor laser device 1 that is located outwardly of the ridge waveguide and on which is deposited the solder layer 61. The complete adherent layer 33 is formed on both sides of the incomplete adherent layer 31 in the widthwise direction Y. That is, the complete adherent layer 33 is so formed as to extend from the incomplete adherent layer 31 to the end of the semiconductor laser device 1 in the widthwise direction Y.

The complete adherent layer 33 is also formed in the terrace portion 8-sided part of the concavity 15. The complete adherent layer 33 portion located in the concavity 15 extends a predetermined distance L7 from the terrace portion 8 partway to the ridge portion 7. The predetermined distance L7 is set at or below 50% of the predetermined distance L2 between the ridge portion 7 and the terrace portion 8.

Moreover, the semiconductor substrate 2 has formed on its other Z direction-wise surface a back-side electrode layer 36 made of gold (Au), or the back-side metal layer. The back-side electrode layer 36 is deposited over the entire other Z direction-wise surface 2b of the semiconductor substrate 2. In contrast to the plate electrode layer 27, the back-side electrode layer 36 has a thickness ranging from 1000 Å to 3000 Å.

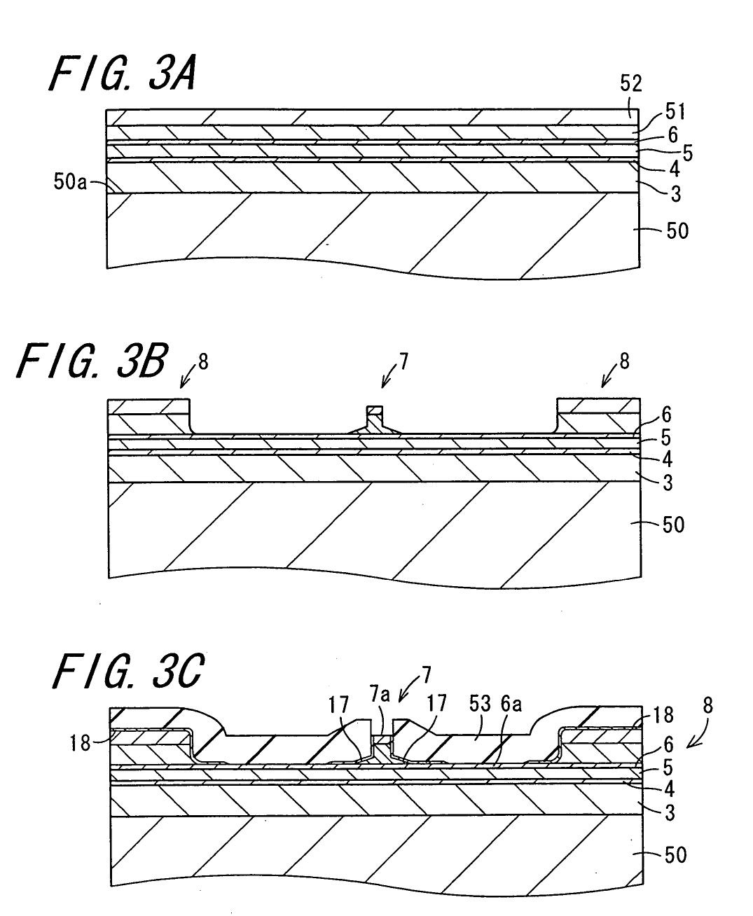

FIGS. 3A through 3C, 4A through 4D, and 5A through 5C are sectional views showing how the semiconductor laser device 1 is fabricated. At the outset, as shown in FIG. 3A, on one surface 50a of a precursor 50 of the semiconductor substrate 2 ranging in thickness from 300 μm to 350 μm are successively deposited the 2.0 μm-thick first clad layer 3, the active layer 4, the second clad layer 5 ranging in thickness from 0.2 μm to 0.3 μm, the 50 Å-thick etching stop layer 6, a first precursor layer 51 made of p-type (Al_{0.7} Ga_{0.3}) 0.5In_{0.5} P for forming the third clad layer 11 and the first terrace constituting layer 13, and a second precursor layer 52 for forming the cap layer 12 and the second terrace constituting layer 14 in the order named by means of epitaxial growth technique using a molecular beam epitaxial (MBE for short) apparatus or a metal organic chemical vapor deposition (MOCVD for short) apparatus. In forming the active layer 4, the first and second well layers are each set at 80 Å in thickness, the barrier layer is set at 50 Å in thickness, and the first and second guide layers are each set at 300 Å in thickness.

Next, as shown in FIG. 3B, part of the first and second precursor layers 51 and 52 are removed by means of photolithography and etching techniques to create the ridge portion 7 and the terrace portion 8.

Next, a dielectric layer is deposited so as to cover the ridge portion 7, the terrace portion 8, and one Z direction-wise surface 6a of the etching stop layer 6. Subsequently, of the dielectric layer, the portion located on the ridge portion 7 and-part of the portion located on the etching stop layer 6 are removed by means of photolithography and etching techniques to create the first and second dielectric layers 17 and 18.

Next, a resist is applied so as to cover the first and second dielectric layers 17 and 18, a part of one Z direction-wise surface 6a of the etching stop layer 6 which is not covered with the first and second dielectric layers 17 and 18, and one Z direction-wise surface 7a of the ridge portion 7. After that, as shown in FIG. 3C, a part of the resist which is located on one Z direction-wise surface 7a of the ridge portion 7 is removed by means of photolithography and etching techniques to create a resist pattern layer 53.

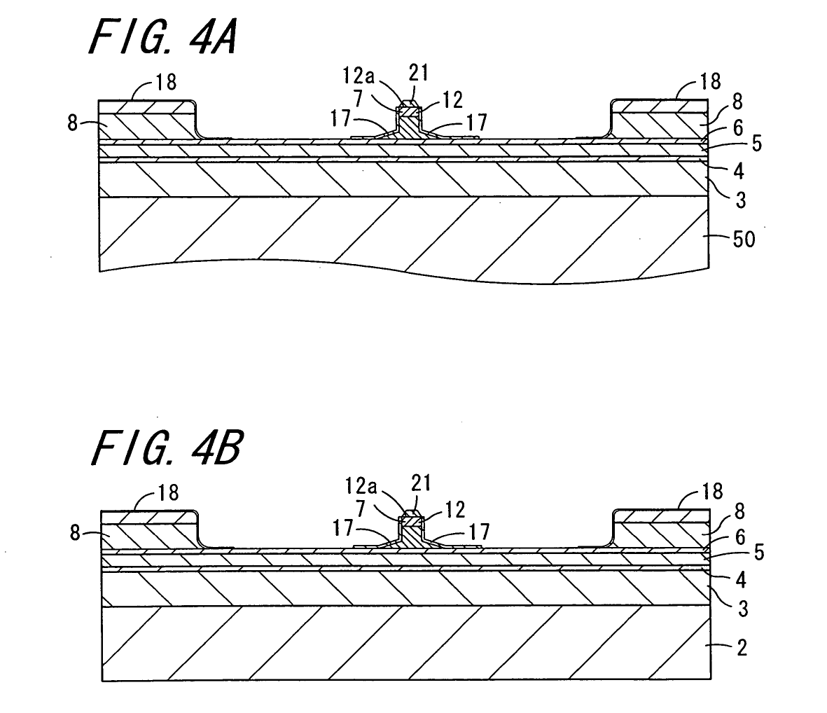

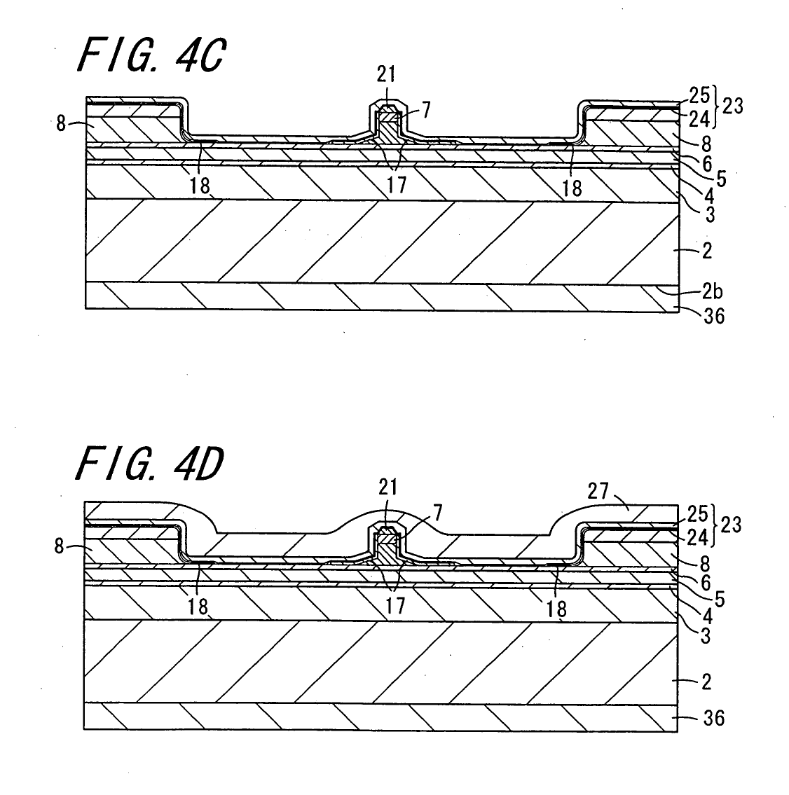

Next, a third precursor layer made of AuZn is vapor-deposited, in a film thickness ranging from 400 Å to 3000 Å, so as to cover one Z direction-wise surface 7a of the ridge portion 7 and the resist pattern layer 53. The third precursor layer, except for the region deposited on the ridge portion 7, is then removed together with the resist pattern layer 53 by means of lift off technique. In this way, as shown in FIG. 4A, the ridge top electrode layer 21 is formed on one Z direction-wise surface 12a of the cap layer 12.

Next, as shown in FIG. 4B, the precursor 50 of the semiconductor substrate 2 is subjected to polishing until a predetermined thickness is obtained. More specifically, the other Z direction-wise surface of the precursor 50 is polished to the predetermined thickness ranging from 50 μm to 130 μm, thereby constituting the semiconductor substrate 2.

Next, as shown in FIG. 4C, on the other Z direction-wise surface 2b of the semiconductor substrate 2 is formed the back-side electrode layer 36. Then, the ridge top electrode layer 21 and the back-side electrode layer 36 are subjected to an alloying process in an atmosphere of nitrogen gas.

Next, as shown in FIG. 4C, on the side of one Z direction-wise surface 2a of the semiconductor substrate 2, Ti is vapor-deposited, in a layer thickness ranging from 1000 Å to 2000 Å, so as to cover the first and second dielectric layers 17 and 18, the ridge top electrode layer 21, and the etching stop layer 6 to create the first plating underlayer 24. Moreover, Au is vapor-deposited thereon in a layer thickness ranging from 500 Å to 1500 Å to create the second plating underlayer 25. In this way, the plating base electrode layer 23 is formed.

Next, the plating base electrode layer 23 is subjected to feeding to carry out electrolytic Au plating for a predetermined period of time. In this way, as shown in FIG. 4D, there is formed the plate electrode layer 27 having layer thickness of 0.5 μm or more and less than 5.0 μm.

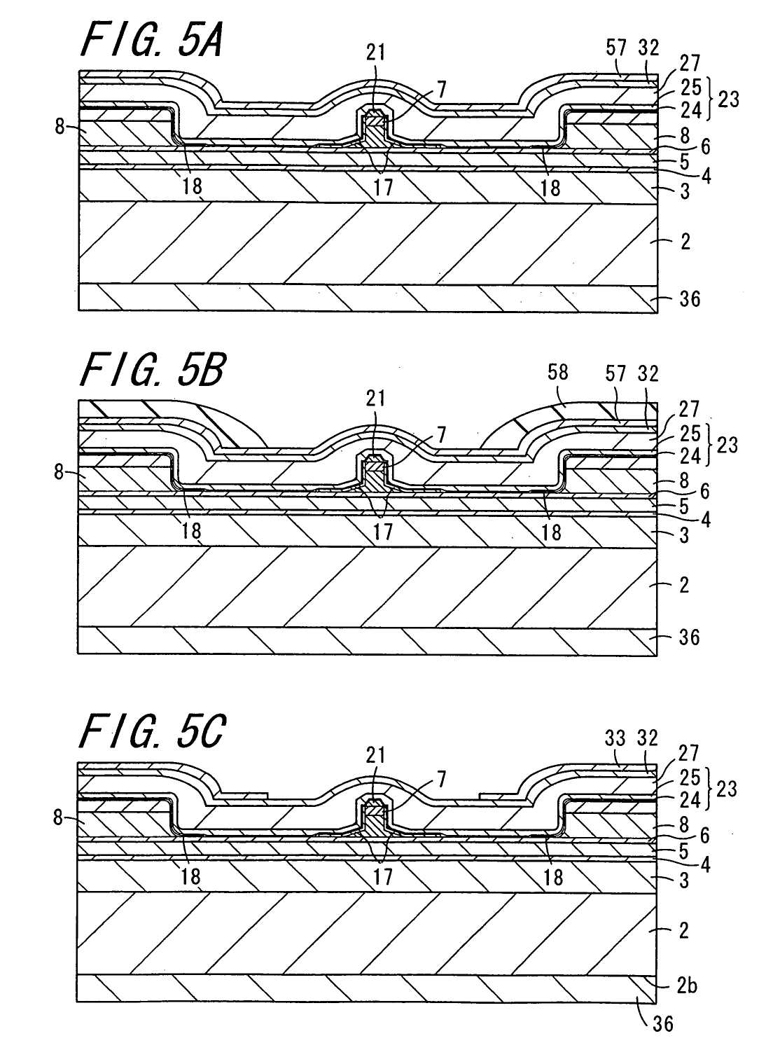

Next, as shown in FIG. 5A, Mo is vapor-deposited onto one Z direction-wise surface 27a of the plate electrode layer 27 to create the metal layer 32. Subsequently, Au is vapor-deposited onto one Z direction-wise surface 32a of the metal layer 32 to create a fourth precursor layer 57.

Next, a resist is applied onto one Z direction-wise surface 57a of the fourth precursor layer 57. After that, a part of the resist overlying the metal layer 32 is removed by means of photolithography and etching techniques to expose a part of the fourth precursor layer 57 which is deposited on a certain region of the metal layer 32 to be formed into the incomplete adherent layer 31. In this way, as shown in FIG. 5B, a resist pattern layer 58 is formed. The width of the resist pattern layer 58-masked region as well as the Y direction-wise dimension of a part of the metal layer 32 which is not covered with the resist pattern layer 58 is set at approximately 20 μm. That is, if it is assumed that the exposed metal layer 32 is divided into two portions symmetrically arranged in respect to a virtual plane passing through the center of the ridge portion 7 in a direction perpendicular to the widthwise direction Y, then the two portions extend oppositely in the widthwise direction Y by approximately 10 μm, respectively. Moreover, when viewed in the direction X in which the ridge portion 7 extends, the metal layer 32 has its both ends covered with the resist pattern layer 58.

Next, a part of the fourth precursor layer 57 which is not covered with the resist pattern layer 58 is removed by means of etching technique so as for a part of the metal layer 32 to be exposed. This exposed part of the metal layer 32 constitutes the incomplete adherent layer 31. Moreover, upon part of the fourth precursor layer 57 and the resist pattern layer 58 being removed, as shown in FIG. 5C, the complete adherent layer 33 is created on either side of the incomplete adherent layer 31 in the widthwise direction Y.

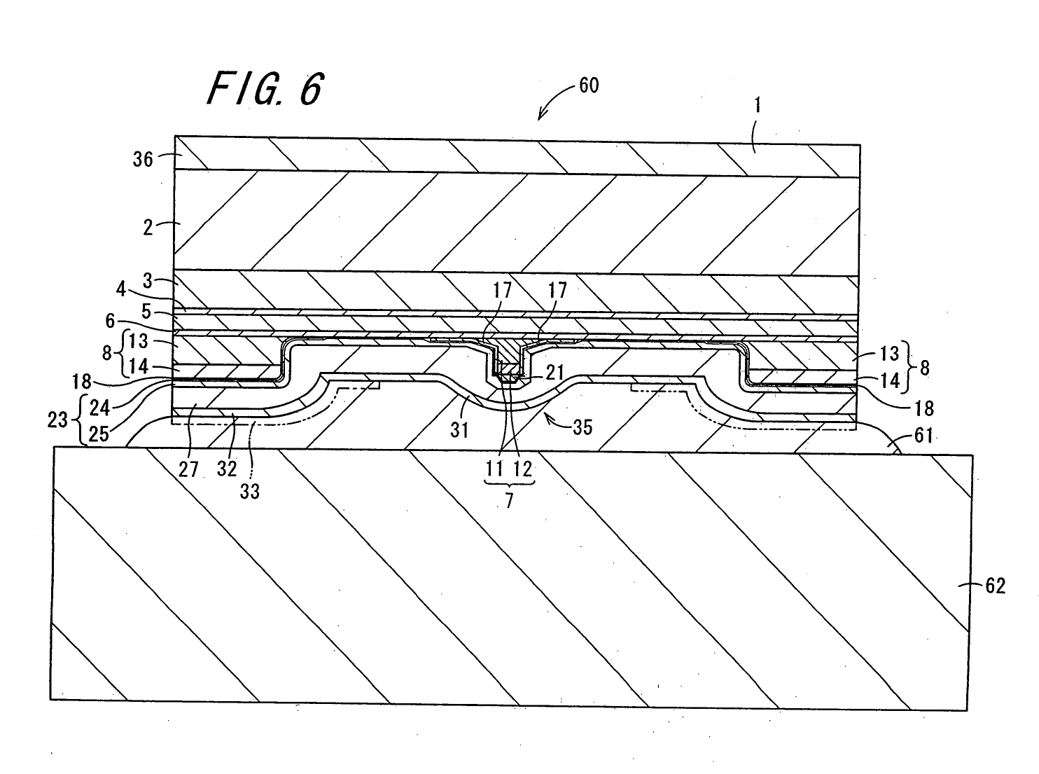

FIG. 6 is a sectional view showing a semiconductor laser apparatus 60 constructed by mounting the semiconductor laser device 1 onto the mount 62, with the solder layer 61 lying therebetween. The semiconductor laser device 1 can be mounted onto the mount 62 by depositing the solder layer 61 on the incomplete adherent layer 31 and the complete adherent layer 33 by means of die bonding. The solder material used for forming the solder layer 61 is made of AuSn. In the present embodiment, the solder material has a Au content of 70% and a Sn content of 30%. The mount 62 is of a so-called sub mount, which is made of a material having high electrical conductivity and also high thermal conductivity, such as aluminum nitride (AlN).

The semiconductor laser device 11 is die-bonded to the mount 62 under predetermined die-bonding conditions including a loading condition as to the level of load application required to mount the semiconductor laser device 1 onto the mount 62 and a heating condition as to the level of heat application required to mount the semiconductor laser device 1 onto the mount 62.

Application of a physical load is necessary to press the semiconductor laser device 1 against the solder layer 61 deposited on the mount 62. However, if an unduly heavy load, for example, a load of 1.0 N (newton) is imposed on the semiconductor laser device 1, the inner structure thereof such as the ridge structure 35 and the first and second dielectric layers 17 and 18 will be subjected to a high pressing stress, thus causing distortion in the ridge structure 35, and, as the worst case, there may occur breakage of the semiconductor laser device 1 in itself. By way of contrast, if an unduly light load, for example, a load of 0.05 N is imposed, the semiconductor laser device 1 cannot be pressed sufficiently against the solder layer 61 deposited on the mount 62, thus causing a failure of bonding and eventually causing separation. Although it will thus be seen that the mounting load is preferably selected to be greater than 0.05 N and less than 1.0 N, from the standpoint of achieving mounting successfully with minimum loading, it is more preferable that the mounting load is selected to fall in a range of from 0.1 N to 0.3 N.

Moreover, application of heat is necessary to cause the solder layer 61 deposited on the mount 62 to melt so that the Au-made complete adherent layer 33 present on the outermost die-bonded surface of the semiconductor laser device 1 can be alloyed with the solder layer 61. The mount 62 is placed on a heater to effect heating. At this time, if the mount 62 is heated excessively, for example, if it is heated at 360 ° C (degree) for 30 s (seconds) and is thereafter forcibly cooled down for one second to approximately 200° C. with use of a blower, then a stress will be developed in the layer stacking arrangement existing within the semiconductor laser device 1 due to layer peeling and separation resulting from differences in thermal expansion coefficient, variation in physical properties, an alloying reaction, or other factors. This results in occurrence of distortion. By way of contrast, if the mount 62 is heated insufficiently, for example, if it is heated at 280° C. for 0.3 s and is thereafter forcibly cooled down for one second to approximately 200° C. with use of a blower, then the semiconductor laser device 1 cannot be bonded properly to the solder layer 61 deposited on the mount 62 because of a failure of alloying, thus causing separation. In light of the foregoing, it is preferable that the mount 62 is heated at a temperature of higher than 200° C. and lower than 360° C. for greater than 0.3 and less than 30 seconds. From the standpoint of achieving bonding successfully with minimum heating, the heating condition should preferably be such that 300° C. and approximately 2 seconds.

The heating temperature condition depends to a large degree on the thickness of the complete adherent layer 33 present on the outermost die-bonded surface of the semiconductor laser device 1. By setting the heating temperature at 300° C. and the heating duration at approximately 2 seconds in consideration of minimum heating, it is possible to reduce the thickness of the complete adherent layer 33 to, for example, 0.12 μm, and thereby allow the complete adherent layer 33 to be alloyed in a shorter period of time.

An alloying reaction between the solder material AuSn constituting the solder layer 61 and Au constituting the complete adherent layer 33 starts, that is, AuSn and Au of the complete adherent layer 33 are alloyed with each other, while being pressed against each other under the predetermined loading and heating conditions. In an alloying process of AuSn and Au, at first AuSn is caused to melt by heating, and the molten AuSn is adhered to the surface of the complete adherent layer 33, and then, as the heating process continues, the adherent AuSn is diffused into the complete adherent layer 33. As to the direction of diffusion, AuSn travels in the direction of thickness of the complete adherent layer 33, and then starts to diffuse at certain several points (diffusion points) on the surface of the complete adherent layer 33. As the heating process continues further, the number of the diffusion points is increased and simultaneously the diffusion point changes its shape from a spot to a circle. The speed and depth at which AuSn travels in the thickness wise direction Z of the complete adherent layer 33 depend upon the ratio in absolute amount between the solder material AuSn and Au constituting the complete adherent layer 33, namely the mass ratio, and the level of heating. The time to be spent in completing the diffusion also depends upon the aforementioned factors. By increasing the amount of the solder material relatively to the amount of Au constituting the complete adherent layer 33 and also raising the level of heating, it is possible to allow the complete adherent layer 33 to be alloyed instantly on contact with AuSn. Accordingly, the complete adherent layer 33 present on the outermost die-bonded surface of the semiconductor laser device 1 is formed in the manner as described hereinabove, and the amount of the solder material is increased. In this state, the heating operation is discontinued at the instant when AuSn starts to diffuse, and the diffusion is thereupon no longer in process.

Of one outermost surface of the semiconductor laser device 1 in the thickness wise direction Z of the semiconductor substrate 2, the region corresponding to the ridge structure 35 is composed of the incomplete adherent layer 31 made of Mo. Although the AuSn-made solder material makes intimate contact with the incomplete adherent layer 31, in the absence of Au, no alloying reaction takes place therebetween. That is, the solder material AuSn deposited on the mount 62 is alloyed only with the complete adherent layer 33, and the incomplete adherent layer 31 is adhered to the solder layer 61 incompletely. Accordingly, at the time of mounting the semiconductor laser device 1 onto the mount 62, the incomplete adherent layer 31 is less subjected to a stress exerted by the solder layer 61 compared to the complete adherent layer 33.

In order for the semiconductor laser device 1 to be mounted onto the mount 62 to construct the semiconductor laser apparatus 60, the solder material is deposited over the entire one Z direction-wise surface of the semiconductor laser device 1. In this case, in contrast to the case of applying the solder material to one Z direction-wise surface of the semiconductor laser device 1 in part, the mounting can be achieved with ease.

The semiconductor laser apparatus 60 employing the semiconductor laser device 1 of the invention (hereafter occasionally referred to as “the semiconductor laser apparatus of Example 1”) and another semiconductor laser apparatus employing a semiconductor laser device implemented for comparison purposes (hereafter occasionally referred to as “the semiconductor laser apparatus of Comparative example”) were actually fabricated to examine polarization characteristics. In the semiconductor laser apparatus of Comparative example, Au-made alloying layer is deposited over the entire one Z direction-wise surface 32a of the metal layer 32 of the semiconductor laser device 1. The alloying layer is identical in thickness with the complete adherent layer 33.

The semiconductor laser device 1 and the semiconductor laser device of Comparative example were fabricated as follows. At first, a single wafer made of p-type GaAs is prepared for use. Then, following the formation of the fourth precursor layer as shown in FIG. 5A, the wafer is divided into two pieces. In one of the two wafers are formed a plurality of the semiconductor laser devices 1 having the incomplete adherent layer 31 in accordance with the above stated method, whereas in the other wafer are formed a plurality of the semiconductor laser devices of Comparative example.

The semiconductor laser device 1 and the semiconductor laser device of Comparative example thus fabricated were each bonded to the mount 62 with use of a solder material under the above stated die-bonding conditions. The semiconductor laser devices bonded to the mount 62 were each mounted onto a 5.6 φ stem, that is a stem having a diameter of 5.6 mm, with use of Ag paste, followed by performing wire bonding and cap sealing process. The semiconductor laser apparatuses thus constructed were subjected to a burn-in test under the same condition before conducting the measurement of laser polarization characteristics. Listed in Table 1 is the data about the polarization characteristics of Example 1 and Comparative example measured as polarization ratio and polarization angle.

TABLE 1

| Polarization | | Comparative |
|---|---|---|
| characteristics | Example 1 | example |
| Polarization ratio | 343 | 174 |
| (Ave) | | |
| Polarization ratio | 79 | 112 |
| (σ) | | |
| Polarization angle | 1.6 | −2.1 |
| (Ave) | | |
| Polarization angle | 1.1 | 3.5 |
| (σ) | | |

Polarization ratio measurement was made on a plurality of, herein, 30 pieces of the semiconductor laser devices. In Table 1, Polarization ratio (Ave) indicates the average value of all the polarization ratio data, and Polarization ratio (σ) indicates the standard deviation of the average value. Polarization angle measurement was also made on a plurality of, herein, 30 pieces of the semiconductor laser devices. Likewise, Polarization angle (Ave) indicates the average value of all the polarization angle data, and Polarization angle (σ) indicates the standard deviation of the average value. Note that the polarization angle is such as to yield maximum intensity of laser light that has been received at a light-receiving section through a polarizing filter adapted to a specific direction of polarization, which is arranged in parallel with a laser light emitting direction, when the polarizing filter is angularly deviated by 90 degrees.

As will be understood from Table 1, the semiconductor laser apparatus of Example 1 is larger in polarization ratio, smaller in polarization angle, and smaller in variations in polarization ratio and polarization angle than the semiconductor laser apparatus of Comparative example. In the semiconductor laser apparatus of Comparative example, upon the semiconductor laser device being mounted onto the sub mount under the above stated die-bonding conditions, the Au-made alloying layer present on the outermost die-bonded surface is alloyed with AuSn deposited on the submount. Since an alloying reaction takes place also in the outermost surface portion corresponding to the ridge structure 35 without fail, it follows that the operating current (rated current) Iop can be kept low with stability at a high temperature. However, looking at the data obtained by the laser characteristics measurement conducted at an ambient temperature, it will be seen that, in a plurality of the semiconductor laser devices having the same structure, the average value (Ave) of polarization ratio is small and the standard deviation (σ) value of polarization ratio is large. Furthermore, the average value (Ave) of polarization angle goes negative, and the standard deviation (σ) value of polarization angle is large. This is because, when the solder material is diffused into the ridge structure 35 from without and alloyed with the alloying layer present on the outermost surface of the semiconductor laser device, the ridge structure 35 undergoes an alloying reaction and simultaneously the ridge portion 7 is covered with AuSn, thus producing a stress that could cause distortion. In accompaniment with the alloying reaction between the Au-made alloying layer and the AuSn-made solder material, the ridge structure 35 is subjected to a pressing force and a pulling force. These forces are believed to be the true nature of the stress that could cause distortion. <

Furthermore, below the Au-made alloying layer overlying the ridge structure 35 are formed base layers including the Mo-made metal layer 32, the Au-made plate electrode layer 27, and the plating base electrode layer 23. The stress resulting from the alloying reaction between the alloying layer and the solder material presumably exerts an influence upon these base layers, too. That is, these base layers are also likely subjected to pressing and pulling forces. Of the stress, presumably, the pressing force arises when the solder material is caused to expand through application of heat, whereas the pulling force arises when the heated solder material is cooled down subsequently. Accordingly, so long as the solder material is caused to expand, makes contact with the ridge structure 35, and is caused to contract in a uniform manner, the ridge structure 35 is subjected to a uniform stress, which results in reduction in the degree of distortion. This makes it possible to bond the semiconductor laser device in substantially bare chip (raw chip) form to the sub mount. In reality, however, the solder material is caused to expand and contract differently from part to part. Therefore, during the heating process, the ridge structure 35 is subjected partly to a strong pressing force and partly to a weak pressing force. This gives rise to lack of uniformity in the alloying reaction, wherefore a stress is generated locally. As the uneven alloying reaction is going on, the heating is discontinued to effect cooling, and the solder material thereupon starts to contract. At this time, the ridge structure 35 is subjected partly to a strong pulling force and partly to a weak pulling force, in addition to strong and weak pressing forces. The contraction-induced pulling and pressing forces presumably exert a stress upon the ridge structure 35. Moreover, during the cooling process, contraction arises in the alloyed AuSn layer formed by the alloying reaction between the alloying layer present in the outermost part of the ridge structure 35 and the solder material. Note that AuSn is a solder material of the type that is hardly alloyed with the Mo-made metal layer 32 underlying it, or, if anything, comes off, in a temperature range of from 300° C. to 400° C. in which AuSn is thermally bondable. In the semiconductor laser apparatus of Comparative example, since the alloying layer and the metal layer 32 are deposited on each other by means of sputtering, it is presumable that the metal layer 32 is pulled by the alloying layer in an alloyed state, and is thus subjected to a significant stress. As described hereinabove, in the semiconductor laser apparatus of Comparative example, the metal layer 32 is subjected to a stress that could cause distortion, and the stress further exerts an influence upon the base layers underlying the metal layer 32, and eventually the ridge portion 7 of the ridge structure 35, which is the principal part of the semiconductor laser device, is affected by the stress. As a result, the ridge portion 7 is likely to suffer from an undesirable deformation. Hence, since application of an uneven stress to the ridge structure 35 leads to deterioration in the laser characteristics, it is of particular importance to exert a stress uniformly upon the ridge structure 35 to reduce the degree of distortion. Presumably, the presence of the alloyed AuSn layer in the outermost part of the ridge structure 35 is responsible for the occurrence of an uneven stress. Accordingly, by designing the semiconductor laser device in such a way that the outermost part of the ridge structure 35 is free from an alloying reaction, it is possible to make a resultant stress uniform, and thereby suppress distortion. As a result, deterioration in the laser characteristics can be avoided.

The results of the polarization characteristics measurement made on Example 1 and Comparative example showed that the ridge structure 35 has distortions thereof reduced according to a way of exerting a stress upon the ridge structure 35 whereby an improvement can be achieved in polarization characteristics.

Moreover, it has been confirmed that, in the semiconductor laser apparatus 60 of Example 1, the AuSn-made solder material deposited on the mount 62 and the complete adherent layer 33 react with each other into alloy while the AuSn and the incomplete adherent layer 31 are not under the alloying reaction, that is, the AuSn and the incomplete adherent layer 31 do not react with each other and thus not formed into alloy, when actually observed in the cross section.

As described heretofore, the semiconductor laser apparatus 60 employing the semiconductor laser device 1 offers excellent laser polarization characteristics in an assembly-finished state. That is, according to the results of the polarization characteristics measurement, the polarization ratio can be increased with reduced variation, and the polarization angle can be decreased with reduced variation. The enhancement of the polarization ratio allows stabilization of the semiconductor laser apparatus 60 in terms of optical output. Moreover, by decreasing the polarization angle and minimizing its variation, it is possible to suppress the fluctuation of laser light intensity in FFP radiation characteristics, as well as to reduce radiation noise at the time of emitting laser light.

Otherwise, the invention affords the following advantageous features. In the semiconductor laser apparatus 60, when viewed in the widthwise direction Y, the complete adherent layer 33 is formed on either side of the incomplete adherent layer 31. This makes it possible to strengthen the mechanical coupling between the semiconductor laser device 1 and the mount 62.

In the semiconductor laser apparatus 60, the concavity 15 has formed in its ridge structure 35-sided part the incomplete adherent layer 31. This helps reduce the stress applied to the ridge structure 35 from without even further. At the interface between the ridge structure 35 and the solder layer 61, heat generated in the ridge structure 35 in accompaniment with the emission of laser light cannot be dissipated swiftly. In this respect, since the concavity 15 has formed in its terrace portion 8-sided part the complete adherent layer 33, it follows that the generated heat can be dissipated efficiently from the complete adherent layer 33 into the mount 62 through the solder layer 61.

In the semiconductor laser apparatus 60, the predetermined distance L5 is selected to be 30% or more and less than 50% of the predetermined distance L2 between the ridge portion 7 and the terrace portion 8. By setting L5 at or above 30% of L2, it is possible to alleviate a stress more reliability. On the other hand, by setting L5 to be less than 50% of L2, is possible to avoid deterioration in the amperage characteristics of the semiconductor laser device resulting from a failure of smooth dissipation of heat from the ridge waveguide into the solder layer.

In the semiconductor laser apparatus 60, the predetermined distance L7 is set at or below 50% of the predetermined distance L2 between the ridge portion 7 and the terrace portion 8. This makes it possible to inhibit the stress developed in the complete adherent layer 33 from being transmitted to the ridge structure 35, and thereby reduce the degree of distortion in the ridge structure 35 even further.

In the semiconductor laser device 1, the Ti-made first plating underlayer 24 is partly kept in contact with the epitaxially grown etching stop layer 6 in the region between the ridge portion 7 and the terrace portion 8. In order to see to it that no electric current flows through a part of the first plating underlayer 24 which makes contact with the etching stop layer 6, the ridge top electrode layer 21, which acts as an ohmic electrode, is deposited exclusively on the ridge portion 7. Since the first plating underlayer 24 and the etching stop layer 6 make no ohmic contact with each other to achieve low resistance, it is possible to concentrate the flow of an electric current on the ridge portion 7 where the ridge top electrode layer 21 and the cap layer 12 make ohmic contact with each other.

In the semiconductor laser apparatus 60, the part immediately below the light-emitting point, namely the part extending from the light-emitting point toward the mount 62 in the thickness wise direction Z, and nearby areas are not alloyed with the solder layer 61. Therefore, the level of heat dissipation is decreased around this region. In the semiconductor laser apparatus 60, while a minute cavity is created between the side face of the ridge structure 35 and the solder layer 61, the top portion of the ridge structure 35 is kept in intimate contact with the solder layer 61, with no cavity is present therein. Herein, the top portion of the ridge structure 35 refers to the part deposited on one Z direction-wise surface 7a of the ridge portion 7, and the side face of the ridge structure 35 refers to all the regions other than the top portion. The top portion of the ridge structure 35 (the region immediately below the ridge waveguide), although it is not alloyed with the solder material, is in a heat conductive state because of the contact with the solder layer 61 via which heat is transmitted from the incomplete adherent layer 31 to the mount 62. However, it will be insufficient if heat dissipation takes place only at the top portion of the ridge structure 35. Therefore, the thickness of the Au-made plate electrode layer 27 is increased enough to allow the heat generated in the ridge structure 35 to travel through the plate electrode layer 27 made of gold (Au) having a high thermal conductivity to the terrace portion 8, thus by-passing the heat transmission path. In this way, the heat can be dissipated through the solder layer 61 into the mount 62. This makes it possible to solve the problem of heat dissipation insufficiency in the region between the incomplete adherent layer 31 and the solder layer 61, and thereby enhance the current characteristics even further.

If the thickness of the plate electrode layer 27 is less than 0.5 μm, a satisfactory heat-transmission effect cannot be attained. By way of contrast, if the thickness of the plate electrode layer 27 exceeds 5.0 μm, the wafer will suffer from some warping during the formation of metal layers thereon, which results in poor yields, and further the ridge structure 35 is subjected to a stress that could cause distortion in the presence of the plate electrode layer 27. In light of the foregoing, by adjusting the thickness of the plate electrode layer 27 in a range of from 0.5 μm to 5.0 μm, it is possible to transmit heat from the ridge structure 35 to the complete adherent layer 33 satisfactorily, as well as to alleviate the stress exerted upon the ridge structure 35, thus achieving yield improvements.

If the plate electrode layer 27 is alloyed with a solder material such as AuSn, or heat is applied to a region near the ridge structure 35 when the semiconductor laser device 1 is mounted onto the mount 62 by means of soldering, then there is the risk of deterioration in the laser characteristics. However, as has already been explained, with a combination of the incomplete adherent layer 31 and the complete adherent layer 33, no alloying reaction takes place between the incomplete adherent layer 31 and the solder material; that is, the plate electrode layer 27 can be prevented from being alloyed under protection. Moreover, it is possible to keep the ridge portion 7 away from the heat transmitted through the solder material, and thereby maintain excellent laser characteristics.

Although the embodiment of the invention employs Mo as the material for forming the incomplete adherent layer 31, it is possible to use any other material so long as it lends itself to produce the incomplete adherent layer 31 which is not alloyed with a metal constituting the solder material under the above stated die-bonding conditions.

By way of another embodiment of the invention, in the preceding embodiment, the incomplete adherent layer 31 may be formed of a metal whose wettability with respect to the solder material is lower than that of the metal constituting the complete adherent layer 33. The specific examples of such a metal material include platinum (Pt).

There was fabricated a semiconductor laser apparatus in which the incomplete adherent layer 31 is made of platinum (Pt) (hereafter occasionally referred to as “the semiconductor laser apparatus of Example 2”). Listed in Table 2 is the data about the polarization characteristics of the semiconductor laser apparatus of Example 2. Example 2 has basically the same structure as Example 1, the only difference being the material used to form the incomplete adherent layer 31.

TABLE 2

| Polarization | |
|---|---|
| characteristics | Example 2 |
| Polarization ratio | 235 |
| (Ave) | |
| Polarization ratio | 86 |
| (σ) | |
| Polarization angle | −1.4 |
| (Ave) | |
| Polarization angle | 1.4 |
| (σ) | |

As will be understood from Table 2, the semiconductor laser apparatus of Example 2, although it is second to the semiconductor laser apparatus of Example 1 having the Mo-made incomplete adherent layer 31, is far superior to the semiconductor laser apparatus of Comparative example. It will thus be seen that platinum (Pt) is very acceptable as a metal material for forming the incomplete adherent layer 31.

A metal that exhibits an alloying reaction sharply in a short while, that is, a metal that reacts in a short while to form alloy has a detrimental effect on the polarization characteristics of the semiconductor laser device. By way of contrast, a metal that exhibits a gradual alloying reaction, that is, a metal that is alloyed less easily in a short while, or a metal that exhibits no alloying reaction, that is, a metal that does not form an alloy by reaction, presumably has no or little detrimental effect on the polarization characteristics of the semiconductor laser device. It is thus preferable that the incomplete adherent layer 31 is made of a metal that exhibits a gradual alloying reaction or a metal that exhibits no alloying reaction. The specific examples thereof include Mo and Pt described just above, and Ti. Metal materials Mo, Pt, and Ti are higher in melting point and lower in wettability with respect to the solder material AuSn than Au.

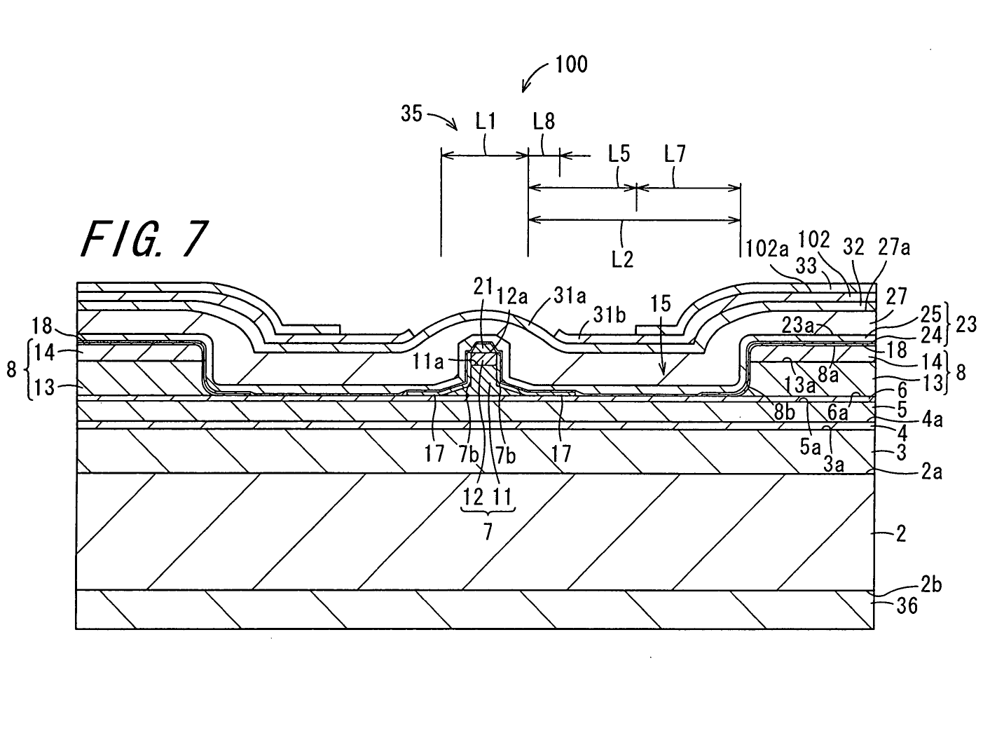

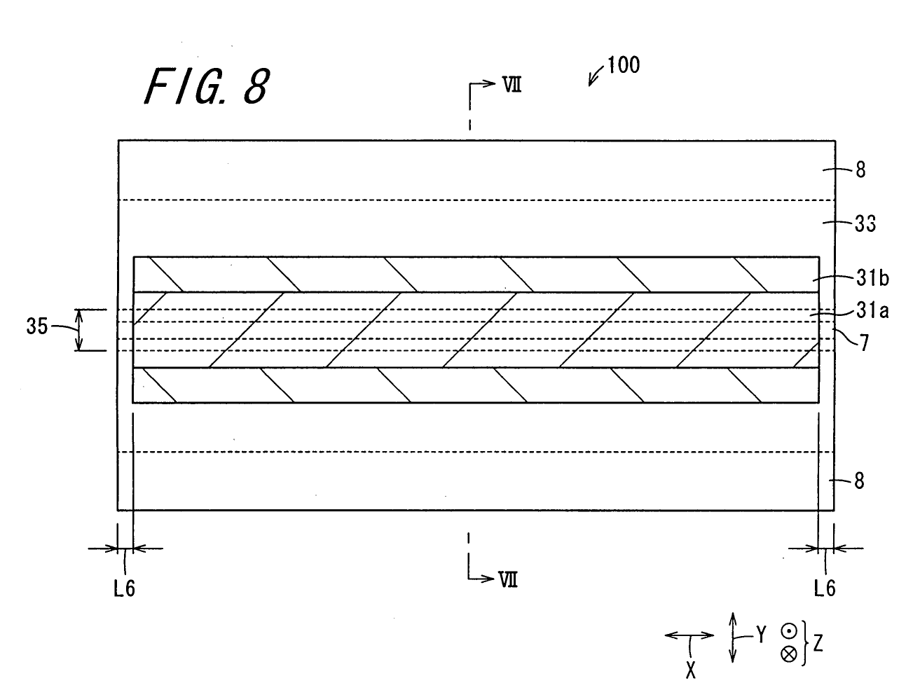

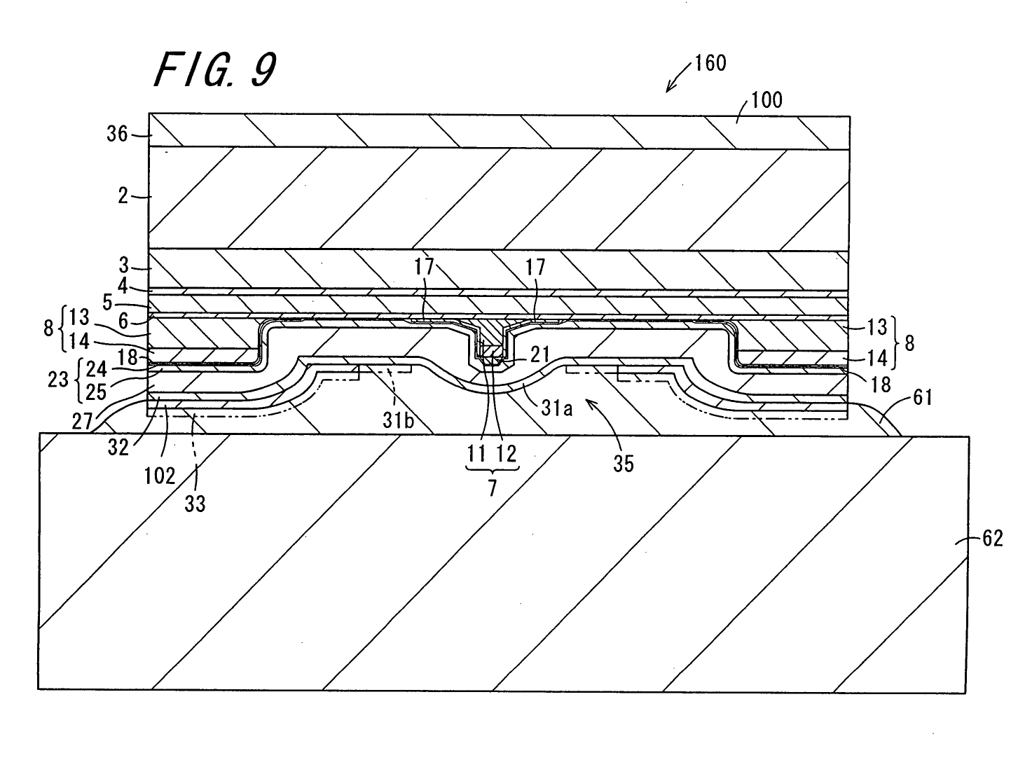

FIG. 7 is a sectional view showing a semiconductor laser device 100 in accordance with still another embodiment of the invention. FIG. 8 is a plan view of the semiconductor laser device 100. FIG. 7 is a sectional view taken along the line VII-VII of FIG. 8. FIG. 8 illustrates one Z direction-wise side of the semiconductor substrate 2 on which is formed the ridge structure 35. In FIG. 8, a first incomplete adherent layer 31a and a second incomplete adherent layer 31b are diagonally shaded for the sake of simplifying an understanding of the illustration.

The semiconductor laser device 100 has basically the same structure as the semiconductor laser device 1 of the preceding embodiment as shown in FIG. 1, except that, in the former, the incomplete adherent layer 31 is composed of the first and second incomplete adherent layers 31a and 31b. Accordingly, the constituent components that play the same or corresponding roles as in the semiconductor laser device 1 will be identified with the same reference symbols, and overlapping descriptions will be omitted.

In the semiconductor laser device 100, between the metal layer 32 and the complete adherent layer 33 such as formed in the semiconductor laser device 1 is interposed an intermediary metal layer 102 including the second incomplete adherent layer 31b. The intermediary metal layer 102 is deposited on one Z direction-wise surface 32a of the metal layer 32. When viewed in the widthwise direction Y, the intermediary metal layer 102 is formed on the metal layer 32 so as to extend from the end of the semiconductor laser device 100 to a position located a predetermined distance L8 away from the ridge structure 35. The predetermined distance L8 is selected to be 30% or more and less than 50% of the predetermined distance L2.

On one Z direction-wise surface 102a of the intermediary metal layer 102 is deposited the complete adherent layer 33. When viewed in the widthwise direction Y, the complete adherent layer 33 is formed on the intermediary metal layer 102 so as to extend from the end of the semiconductor laser device 100 to a position located a predetermined distance L5 away from the ridge structure 35.

Of the metal layer 32, the part which is not covered with the intermediary metal layer 102 constitutes the first incomplete adherent layer 31a. Of the intermediary metal layer 102, the part which is not covered with the complete adherent layer 33 constitutes the second incomplete adherent layer 31b. That is, when viewed in the widthwise direction Y, in the outermost surface portion of the semiconductor laser device 100 that faces the solder layer 61 when mounted onto the mount 62, the first incomplete adherent layer 31a is formed centrally, and the second complete adherent layer 31b is arranged on either side of the first incomplete adherent layer 31a.

The intermediary metal layer 102 is made of a metal which falls in between the metal layer 32 and the complete adherent layer 33 in terms of the extent to which it is wet by the solder material constituting the solder layer 61. That is, the wettability of the metal constituting the intermediary metal layer 102 is higher than that constituting the metal layer 32 but is lower than that constituting the complete adherent layer 33. In the present embodiment, considering that the metal layer 32 is made of Mo and the complete adherent layer 33 is made of Au, then the intermediary metal layer 102 is made of platinum (Pt), for instance. Moreover, the melting point of the metal constituting the intermediary metal layer 102 is lower than that constituting the metal layer 32 but is higher than that constituting the complete adherent layer 33.

The intermediary metal layer 102 is formed by means of vapor deposition, the thickness of which is selected to fall in a range of from 100 Å to 3000 Å.

When viewed in the direction X in which the ridge portion 7 extends, the first, second incomplete adherent layer 31a, 31b is so formed as to extend across both ends of the semiconductor laser device 100, with a predetermined distance L6 secured between each end of the first, second incomplete adherent layer 31a, 31b and the corresponding end face, namely light-emitting surface of the semiconductor laser device 100. The predetermined distance L6 is selected in a manner so as to insure that on the light-emitting surface of the semiconductor laser device 100 is formed a coating film for protection of the light-emitting end face from breakage.

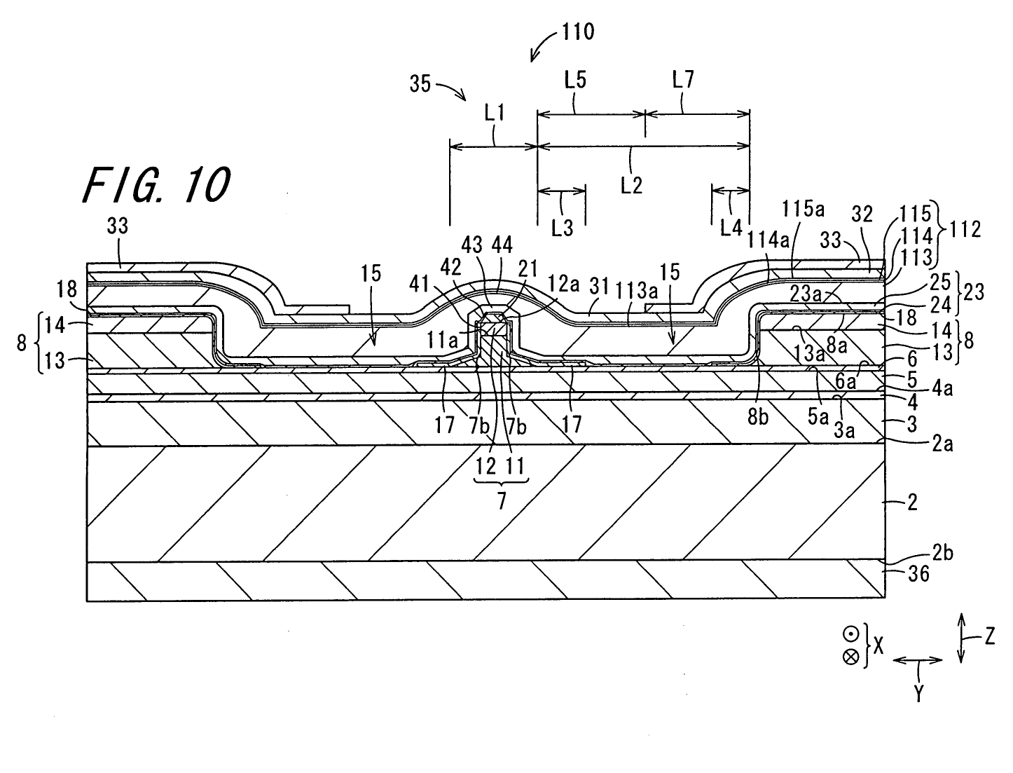

FIG. 9 is a sectional view showing a semiconductor laser apparatus 160 constructed by mounting the semiconductor laser device 100 onto the mount 62, with the solder layer 61 lying therebetween. The semiconductor laser device 100 is bonded to the mount 62 via the AuSn-made solder layer 61 under the above stated die-bonding conditions. The complete adherent layer 33 is alloyed with the solder material, and part of the second incomplete adherent layer 31b is alloyed with the solder material, as well. The second incomplete adherent layer 31b is made of a metal which falls in between the first incomplete adherent layer 31a and the complete adherent layer 33 in terms of the wettability with respect to the solder material constituting the solder layer 61. Correspondingly, the strength of bonding between the second incomplete adherent layer 31b and the solder layer 61 is higher than that between the first incomplete adherent layer 31a and the solder layer 61 but is lower than that between the complete adherent layer 33 and the solder layer 61.

Thus, the semiconductor laser apparatus 160 is so designed that, when viewed in the widthwise direction Y, the strength of bonding between the outermost surface portion on which is deposited the solder layer 61 and the solder layer 61 becomes higher gradually from the center, namely the ridge structure 35 to the edge. By doing so, it is possible to suppress the steep change in stress that occurs in the region where the complete adherent layer 33 and the first, second incomplete adherent layer 31a, 31b are adjacent to each other due to the stress developed in the complete adherent layer 33 and the stress developed in the first, second incomplete adherent layer 31a, 31b. As a result, the stress exerted upon the ridge structure 35 can be alleviated, wherefore the ridge structure 35 suffers little from distortion.

Moreover, the first incomplete adherent layer 31a, the second incomplete adherent layer 31b, and the complete adherent layer 33 can be formed of molybdenum (Mo), platinum (Pt), and gold (Au), respectively, with ease by means of conventionally-known layer deposition technique without the necessity of coming up with a new method.

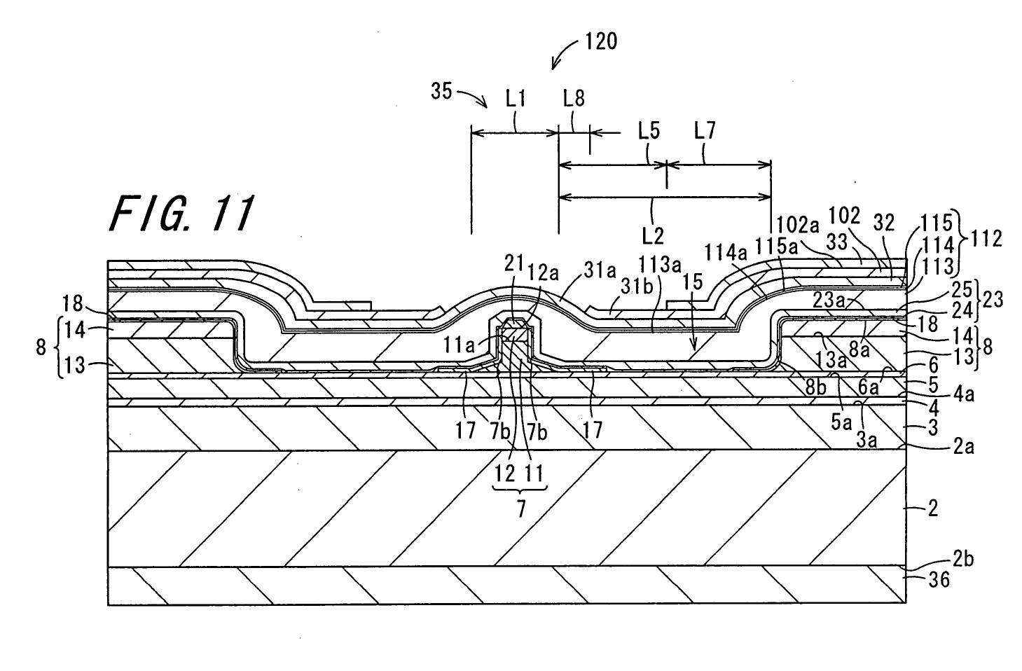

FIG. 10 is a sectional view showing a semiconductor laser device 110 in accordance with still another embodiment of the invention. The semiconductor laser device 110 of the present embodiment has basically the same structure as the semiconductor laser device 1 of the preceding embodiment as shown in FIG. 1, except that a constitution of the plate electrode layer 27 is different from each other. Accordingly, the constituent components that play the same or corresponding roles as in the semiconductor laser device 1 will be identified with the same reference symbols, and overlapping descriptions will be omitted.

The semiconductor laser device 110 is composed of a semiconductor substrate 2, a first clad layer 3, an active layer 4, a second clad layer 5, an etching stop layer 6, a ridge portion 7, a terrace portion 8, a first and a second dielectric layer 17 and 18, a plating base electrode layer 23, an under coating electrode layer 112, a metal layer 32 including the incomplete adherent layer 31, and a complete adherent layer 33.

The under coating layer 112 is composed of a plate electrode layer 113, a first electrode layer 114, and a second electrode layer 115. In the under coating layer 112, the plate electrode layer 113, the first electrode layer 114, and the second electrode layer 115 are deposited in this order. A thickness of the under coating electrode layer 112 is selected to be 0.5 μm or more and less than 5.0 μm.

The plate electrode layer 113 has the same structure, and is thus formed by the same method, as that of the above stated plate electrode layer 27. The plate electrode layer 113 is deposited over the entire one Z direction-wise surface 23a of the plating base electrode layer 23. A thickness of the plate electrode layer 113 is selected to be 0.5 μm or more and less than 5.0 μm, for example, to be 1 μm.

The first electrode layer 114 is formed over an entire one Z direction-wise surface 113a of the plate electrode layer 113. The first electrode layer 114 has better surface flatness than that of the plate electrode layer 113, and is made of a predetermined metal. The predetermined metal is selected from the group consisting of molybdenum (Mo), platinum (Pt), molybdenum-platinum (Moat), and titanium (Ti). By using these metals for forming the first electrode layer 114, it is possible to form the first electrode layer 114 which is excellent in surface flatness. In a case where the first electrode layer 114 is formed of molybdenum (Mo), a thickness thereof is selected to be 0.05 μm or more and less than 0.30 μm, for example, to be 0.05 μm. The first electrode layer 114 is formed by a sputtering method.

The second electrode layer 115 is formed over an entire one Z direction-wise surface 114a of the first electrode layer 114. The second electrode layer 115 is formed of gold. A thickness of the second electrode layer is selected to be 0.05 μm or more and less than 1.0 μm, for example, to be 0.12 μm. Over an entire one Z direction-wise surface 115a of the second electrode layer 115 is deposited the metal layer 32 including the incomplete adherent layer 31. By using gold to form the second electrode layer 115, it is possible to enhance an adhesive property between the under coating electrode layer 112 and the incomplete adherent layer 31 so as to be less easily peeled off from each other. Further, the second electrode layer 115 is formed by the sputtering method as in the case of the first electrode layer 114. The second electrode layer 115 is continuously deposited after the first electrode layer 114 is formed by the sputtering method. The second electrode layer 115 and the first electrode layer 114 are formed by continuously depositing the Mo film and the Au film in a state where a wafer is set in one sputtering apparatus. In a conventional technique, it is required to deposit the Mo film and then, once take the wafer out of the apparatus to reset the wafer in another apparatus, and then deposit the Au film. By contrast, in the embodiment, the wafer is not taken out of the apparatus once, and two samples (Mo and Au) are placed in the apparatus to deposit the Mo film (the first electrode layer 114) and the Au film (the second electrode layer 115) in this order. This makes it possible to continuously deposit the second electrode layer 115 and the first electrode layer 114 without breaking a vacuum state, that is to say, without once exposing the wafer to air. Accordingly, the surface of the Mo-made first electrode layer 114 is not oxidized, with the result that there may be no decrease in adhesion between the first electrode layer 114 and the Au-made second electrode layer 115 deposited thereon.

Concerning a ratio of thickness among the plate electrode layer 113, the first electrode layer 114, and the second electrode layer 115, it is preferred that a thickness of the plate electrode layer 113 (Au) be 1 μm, a thickness of the first electrode layer 114 (Mo) be 0.05 μm, and a thickness of the second electrode layer 115 (Au) be 0.12 μm.

Since the plate electrode layer 113 made of gold is formed by plating, it is possible to form a layer having a large thickness in a short period of time, compared to the case of forming the layer made of gold by the sputtering method. However, the plate electrode layer 113 has deteriorated surface flatness and changing wettability depending on plating conditions. Accordingly, an adhesive property of the plate electrode layer 113 may have variations. According to the invention, on the plate electrode layer 113 are deposited the first electrode layer 114 and the second electrode layer 115 in this order. The first electrode layer 114 has better surface flatness than that of the above stated plate electrode layer 113, and is formed of a predetermined metal. By so doing, it is possible to enhance surface flatness of the second electrode layer 115. It is thus possible to enhance the adhesive property between the second electrode layer 115 and the incomplete adherent layer 31 deposited on the second electrode layer 115, so that the under coating metal layer 112 and the incomplete adherent layer 31 are prevented from being peeled off from each other.

A semiconductor laser apparatus is fabricated, as in the case of the above state semiconductor laser device 100, by mounting the semiconductor laser device 110 onto the mount 62, with the solder layer 61 lying therebetween. In the semiconductor laser device 110 according to the embodiment, the under coating metal layer 112 and the incomplete adherent layer 31 are prevented from being peeled off from each other, so that the heat generated in the ridge structure 35 can be transmitted through the under coating metal layer 112 containing gold (Au) having a high thermal conductivity to the complete adherent layer 33, and then reliably dissipated into the mount 62 through the solder layer 61. In this way, a problem of insufficient heat dissipation can be solved in the region between the incomplete adherent layer 31 and the solder layer 61, thus suppressing deterioration in the current characteristics of the semiconductor laser device 110 more reliably. As a result, a service life of the semiconductor laser device 110 can be made longer.

Further, the first electrode layer 114 and the second electrode layer 115 are formed by continuous deposition of a sputtering method, and therefore able to enhance adhesion thereof to the plate electrode layer 113. Furthermore, even when a surface 113a of the plate electrode layer 113 contains concavities and convexities, the first electrode layer 114 and the second electrode layer 115 are formed so as to pervade every part of the concavities and convexities so that a thickness of the under coating electrode layer 112 can be made as uniform as possible. The more uniformed thickness of the under coating electrode layer 112 can lead a more stabilized bonding property and an enhanced adhesion. This brings effects such that a problem of insufficient heat dissipation can be solved, that current characteristics can be suppressed from being deteriorated, and that a service life of the semiconductor laser device can be made longer.

FIG. 11 is a section view showing a semiconductor laser device in 120 accordance with still another embodiment of the invention. The semiconductor laser device 120 of the present embodiment has basically the same structure as the semiconductor laser device 100 of the preceding embodiment as shown in FIG. 7, except that the plate electrode layer 27 in the semiconductor laser-device 100 is replaced by the under coating electrode layer 112 according to the above stated embodiment as shown in FIG. 10. With such a constitution, the semiconductor laser device 120 can achieve the same effects as those attained in the semiconductor laser device 110 in addition to the above stated effects attained in the semiconductor laser device 100.

By way of further another embodiment of the invention, in the semiconductor laser device in accordance with the embodiments thus far described, instead of forming the etching stop layer 6, the second clad layer 5, the ridge portion 7, and the terrace portion 8 may be formed integrally with one another with use of a common semiconductor material, for example the one used for forming the second and third clad layers 5 and 11, to constitute a single clad layer to be deposited on one Z direction-wise surface 4a of the active layer 4. In this configuration, although the ridge waveguide is susceptible to an external stress, the stress can be alleviated successfully by the incomplete adherent layer 31. Therefore, the same effects as achieved in the preceding embodiments can be achieved. Moreover, the number of epitaxial growth process steps can be reduced, and the time to be spent in the manufacture can be shortened correspondingly. As a result, the semiconductor laser device can be manufactured with higher productivity.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and the range of equivalency of the claims are therefore intended to be embraced therein.

What is claimed is:

1. A semiconductor laser device that is bonded to a mount via a solder layer, comprising:
a ridge structure including a stripe-shaped ridge waveguide that is disposed on a semiconductor substrate;
an electrically conductive incomplete adherent layer which is formed at least in the ridge structure and is to be an outermost surface portion of the semiconductor laser device that is located outwardly of the ridge waveguide and on which is deposited the solder layer, the incomplete adherent layer being brought into contact with the solder layer in an incompletely-adherent state; and
an electrically conductive complete adherent layer which is formed on either side of the incomplete adherent layer and is to be other outermost surface portions of the semiconductor laser device that are located outwardly of the ridge waveguide and on which is deposited the solder layer, when viewed in a direction perpendicular to a direction of thickness of the semiconductor substrate as well as a direction in which the ridge waveguide extends, the complete adherent layer being brought into contact with the solder layer in a completely-adherent state.

2. The semiconductor laser device of claim 1, wherein the incomplete adherent layer is composed of:
a first incomplete adherent layer formed centrally of the semiconductor laser device when viewed in the direction perpendicular to the direction of thickness of the semiconductor substrate as well as the direction in which the ridge waveguide extends; and
a second incomplete adherent layer formed on either side of the first incomplete adherent layer when viewed in the direction perpendicular to the direction of thickness of the semiconductor substrate as well as the direction in which the ridge waveguide extends, the second incomplete adherent layer being designed to fall in between the first incomplete adherent layer and the complete adherent layer in terms of wettability with respect to a solder material used to form the solder layer.

3. The semiconductor laser device of claim 2, wherein the first incomplete adherent layer, the second incomplete adherent layer, and the complete adherent layer are made of molybdenum (Mo), platinum (Pt), and gold (Au), respectively.

4. The semiconductor laser device of claim 1, wherein when viewed in the direction perpendicular to the direction of thickness of the semiconductor substrate as well as the direction In which the ridge waveguide extends, a terrace portion is formed on either side of the ridge waveguide, with a predetermined distance secured therebetween to create a concavity extending from the ridge waveguide to the terrace portion.

5. The semiconductor laser device of claim 4, wherein the concavity has formed in its ridge waveguide-sided part the incomplete adherent layer, and has formed in its terrace portion-sided part the complete adherent layer.

6. The semiconductor laser device of claim 5, wherein a part of the incomplete adherent layer which is located in the concavity extends from a position of the ridge waveguide partway to a position of the terrace portion by a predetermined length which is adjusted to be 30% or more and less than 50% of a distance between the ridge waveguide and the terrace portion.

7. The semiconductor laser device of claim 5, wherein a part of the complete adherent layer which is located in the concavity extends from a position of the terrace portion partway to a position of the ridge waveguide by a predetermined length which is set at or below 50% of the distance between the ridge waveguide and the terrace portion.

8. The semiconductor laser device of claim 1, further comprising an under coating metal layer made of gold (Au) on which are deposited the complete adherent layer and the incomplete adherent layer.

9. The semiconductor laser device of claim 1, further comprising an under coating metal layer on which are deposited the complete adherent layer and the incomplete adherent layer, wherein the under coating metal layer is formed by sequentially depositing a plate electrode layer made of gold (Au) and formed by plating, a first electrode layer made of a predetermined metal, and a second electrode layer made of gold (Au).

10. The semiconductor laser device of claim 9, wherein the predetermined metal which forms the first electrode layer is selected from the group consisting of molybdenum (Mo), platinum (Pt), molybdenum-platinum (Moat), and titanium (Ti).

11. The semiconductor laser device of claim 10, wherein the first electrode layer and the second electrode layer are formed by continuous deposition of a sputtering method.

12. The semiconductor laser device of claim 8, wherein the thickness of the under coating metal layer is selected to be 0.5 μm or more and less than 5.0 μm.

13. The semiconductor laser device of claim 9, wherein the thickness of the under coating metal layer is selected to be 0.5 μm or more and less than 5.0 μm.

14. The semiconductor laser device of claim 8, further comprising a back-side metal layer formed on the opposite surface of the semiconductor substrate from the surface on which is disposed the ridge structure.

15. The semiconductor laser device of claim 9, further comprising a back-side metal layer formed on the opposite surface of the semiconductor substrate from the surface on which is disposed the ridge structure.
